(19) United States
(12) Patent Application Publication
(10) Pub. No.: US 2026/0372035 A1
(43) Pub. Date: Nov. 19, 2026

(54) SEMICONDUCTOR DEVICES AND METHODS OF MANUFACTURE

(71) Applicant: Taiwan Semiconductor Manufacturing Co., Ltd., Hsinchu (TW)

(72) Inventors: Yu-Ju Hsu, Taoyuan County (TW); Ssu-Yu Liao, Hsinchu (TW); Tsu-Hui Su, Taipei City (TW); Chun-Hsiang Fan, Hsinchu (TW)

(21) Appl. No.: 19/751,908

(22) Filed: Jul. 23, 2026

Related U.S. Application Data
(63) Continuation of application No. 18/826,480, filed on Sep. 6, 2024.
(60) Provisional application No. 63/655,173, filed on Jun. 3, 2024.

(51) Int. Cl. H10W 10/17; H10D 30/01; H10D 30/43; H10D 30/67; H10D 62/10; H10D 64/01; H10W 10/00

(52) U.S. Cl. CPC H10W 10/17; H10D 30/014; H10D 30/43; H10D 30/6735; H10D 30/6757; H10D 62/121; H10D 64/017; H10W 10/0145

(57) ABSTRACT

Semiconductor devices and methods of manufacture are presented in which nanostructure devices are formed. In one presented embodiments a method comprises forming a multi-layer stack over a semiconductor substrate, patterning the multi-layer stack into a plurality of fins, the fins being located in a first region and a second region, the first region being a denser region than the second region, rounding corners of the plurality of fins, depositing a first dielectric between the fins, removing a portion of the first dielectric to form a first mask, and forming a gate structure over the first mask.

### PRIORITY CLAIM AND CROSS-REFERENCE

This application is a continuation of U.S. Patent Application 18/826,480 filed Sep. 6, 2024, which application claims the benefit of U.S. Provisional Patent Application No. 63/655,173, filed on Jun. 3, 2024, which applications are hereby incorporated herein by reference.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (nano-FET) in a three-dimensional view, in accordance with some embodiments.

FIGS. 2, 3, 4, 5, 6, 7, 8, 9A, 9B, 10A, 10B, 11A, 11B, 12A, 12B, 13A, 13B, 14A, 14B, 14C, 15A, 15B, 15C, 15D, 16A, 16B, 16C, 17A, 17B, 18A, 18B, 19A, 19B, 20A, 20B, 21A, 21B, 21C, 22A, 22B, 22C, 23A, 23B and 23C are cross-sectional views of intermediate stages in the manufacturing of nano-FETs, in accordance with some embodiments.

FIGS. 24A, 24B and 24C, are cross-sectional views of a nano-FET, in accordance with some embodiments.

FIGS. 25, 26, 27, 28, 29 and 30 illustrate embodiments with a liner, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments will now be described with respect to a particular embodiment in which a mask layer is formed over an isolation region, and wherein the loading between different regions is reduced using a rounding process prior to deposition. However, embodiments are described below in a particular context, a die comprising nano-FETs. Various embodiments may be applied, however, to dies comprising other types of transistors (e.g., fin field effect transistors (FinFETs), planar transistors, or the like) in lieu of or in combination with the nano-FETs.

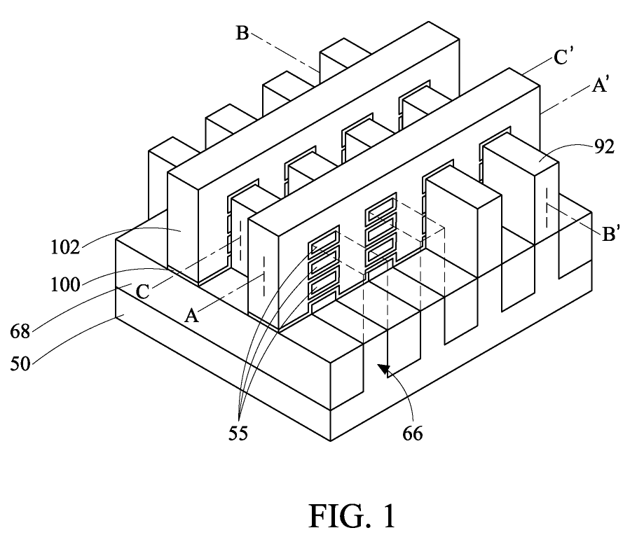

FIG. 1 illustrates an example of nano-FETs (e.g., nanowire FETs, nanosheet FETs (Nano-FETs), or the like) in a three-dimensional view, in accordance with some embodiments. The nano-FETs comprise nanostructures 55 (e.g., nanosheets, nanowire, or the like) over fins 66 on a substrate 50 (e.g., a semiconductor substrate), wherein the nanostructures 55 act as channel regions for the nano-FETs. The nanostructure 55 may include p-type nanostructures, n-type nanostructures, or a combination thereof. STI regions 68 are disposed between adjacent fins 66, which may protrude above and from between neighboring STI regions 68. Although the STI regions 68 are described/illustrated as being separate from the substrate 50, as used herein, the term “substrate” may refer to the semiconductor substrate alone or a combination of the semiconductor substrate and the isolation regions. Additionally, although a bottom portion of the fins 66 are illustrated as being single, continuous materials with the substrate 50, the bottom portion of the fins 66 and/or the substrate 50 may comprise a single material or a plurality of materials. In this context, the fins 66 refer to the portion extending between the neighboring STI regions 68.

Gate dielectric layers 100 are over top surfaces of the fins 66 and along top surfaces, sidewalls, and bottom surfaces of the nanostructures 55. Gate electrodes 102 are over the gate dielectric layers 100. Epitaxial source/drain regions 92 are disposed on the fins 66 on opposing sides of the gate dielectric layers 100 and the gate electrodes 102. Epitaxial source/drain region(s) 92 may refer to a source or a drain, individually or collectively dependent upon the context.

FIG. 1 further illustrates reference cross-sections that are used in later figures. Cross-section A-A’ is along a longitudinal axis of a gate electrode 102 and in a direction, for example, perpendicular to the direction of current flow between the epitaxial source/drain regions 92 of a nano-FET. Cross-section B-B’ is perpendicular to cross-section A-A’ and is parallel to a longitudinal axis of a fin 66 of the nano-FET and in a direction of, for example, a current flow between the epitaxial source/drain regions 92 of the nano-FET. Cross-section C-C’ is parallel to cross-section A-A’ and extends through epitaxial source/drain regions of the nano-FETs. Subsequent figures refer to these reference cross-sections for clarity.

Some embodiments discussed herein are discussed in the context of nano-FETs formed using a gate-last process. In other embodiments, a gate-first process may be used. Also, some embodiments contemplate aspects used in planar devices, such as planar FETs or in fin field-effect transistors (FinFETs).

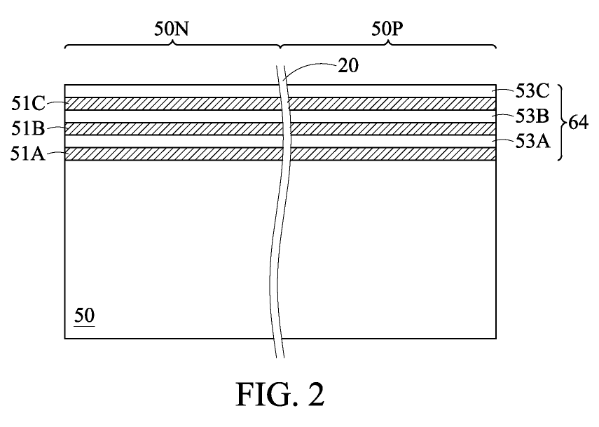

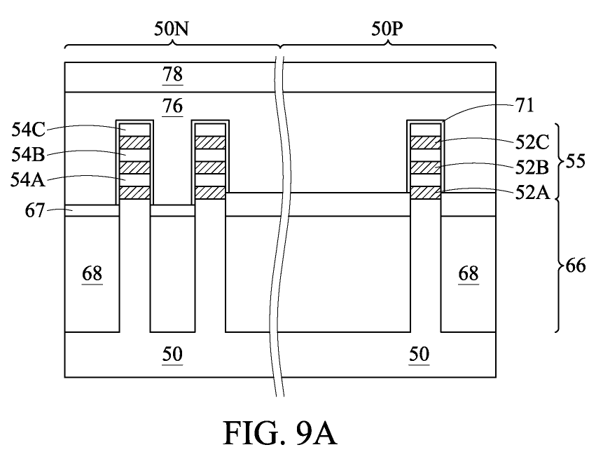

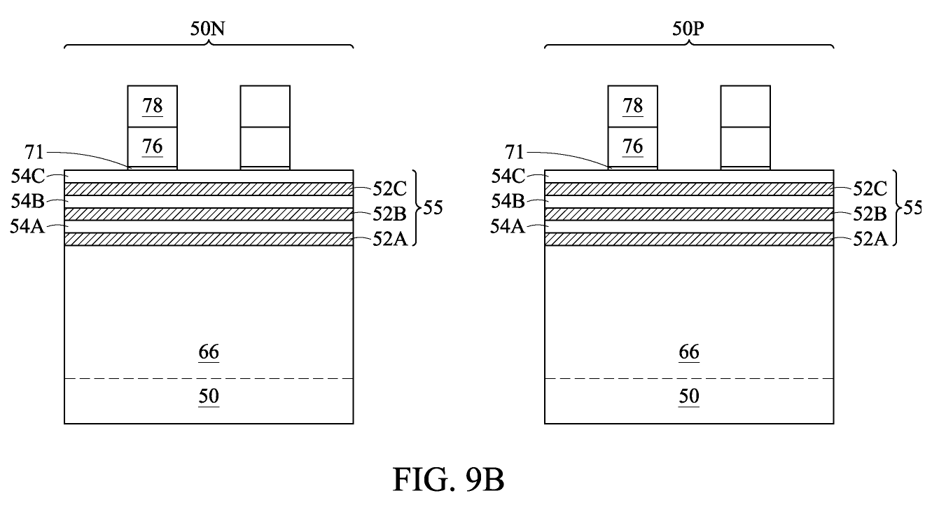

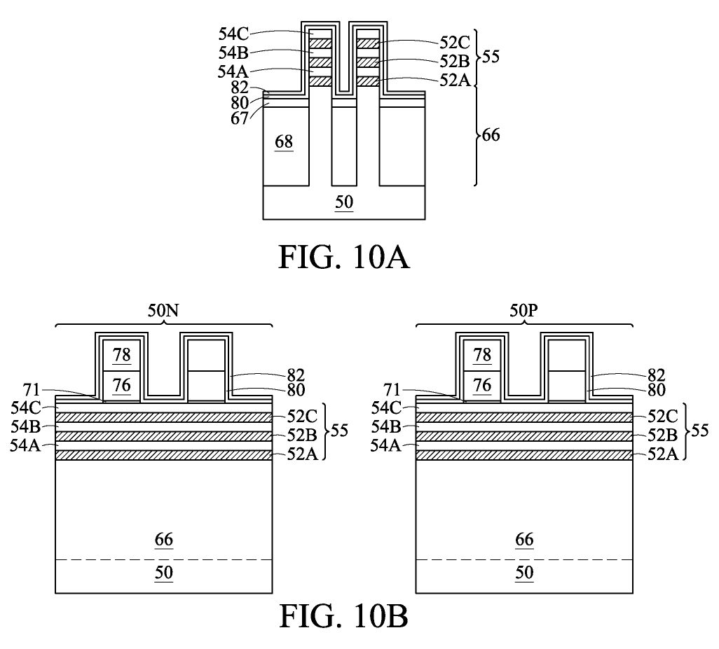

FIGS. 2-23C are cross-sectional views of intermediate stages in the manufacturing of nano-FETs, in accordance with some embodiments. FIGS. 2-9A, 16A, 17A, 18A, 19A, 20A, 21A, 22A, 23A, 24A and 25-30 illustrate reference cross-section A-A’ illustrated in FIG. 1. FIGS. 9B, 10B, 11B, 12B, 13B, 14B, 15B, 15D, 16B, 17B, 18B, 19B, 20B, 21B, 22B, 23B and 24B illustrate reference cross-section B-B’ illustrated in FIG. 1. FIGS. 10A, 11A, 12A, 13A, 14A, 15A, 15C, 16C, 21C, 22C, 23C and 24C illustrate reference cross-section C-C’ illustrated in FIG. 1.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 50 has an n-type region 50N and a p-type region 50P. The n-type region 50N can be for forming n-type devices, such as NMOS transistors, e.g., n-type nano-FETs, and the p-type region 50P can be for forming p-type devices, such as PMOS transistors, e.g., p-type nano-FETs. The n-type region 50N may be physically separated from the p-type region 50P (as illustrated by divider 20), and any number of device features (e.g., other active devices, doped regions, isolation structures, etc.) may be disposed between the n-type region 50N and the p-type region 50P. Although one n-type region 50N and one p-type region 50P are illustrated, any number of n-type regions 50N and p-type regions 50P may be provided.

Further in FIG. 2, a multi-layer stack 64 is formed over the substrate 50. The multi-layer stack 64 includes alternating layers of first semiconductor layers 51A-C (collectively referred to as first semiconductor layers 51) and second semiconductor layers 53A-C (collectively referred to as second semiconductor layers 53). For purposes of illustration and as discussed in greater detail below, the second semiconductor layers 53 will be removed and the first semiconductor layers 51 will be patterned to form channel regions of nano-FETs in the p-type region 50P. Also, the first semiconductor layers 51 will be removed and the second semiconductor layers 53 will be patterned to form channel regions of nano-FETs in the n-type region 50N. Nevertheless, in some embodiments the first semiconductor layers 51 may be removed and the second semiconductor layers 53 may be patterned to form channel regions of nano-FETs in the n-type region 50N, and the second semiconductor layers 53 may be removed and the first semiconductor layers 51 may be patterned to form channel regions of nano-FETs in the p-type region 50P.

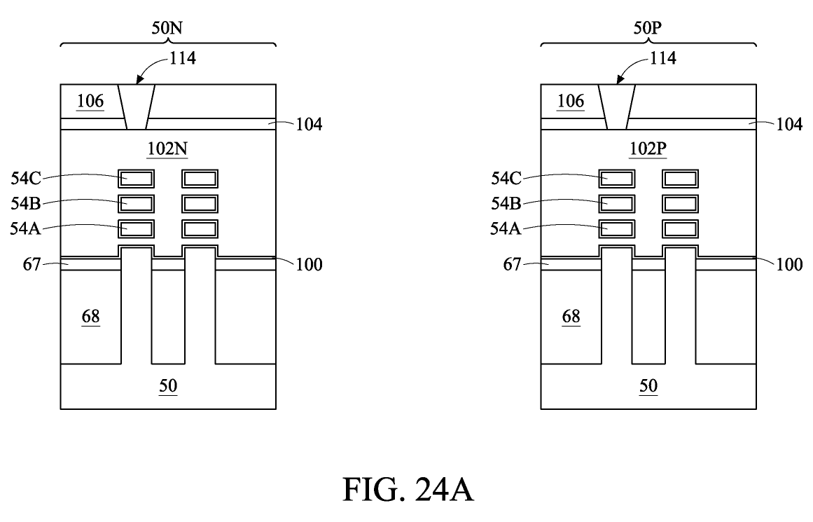

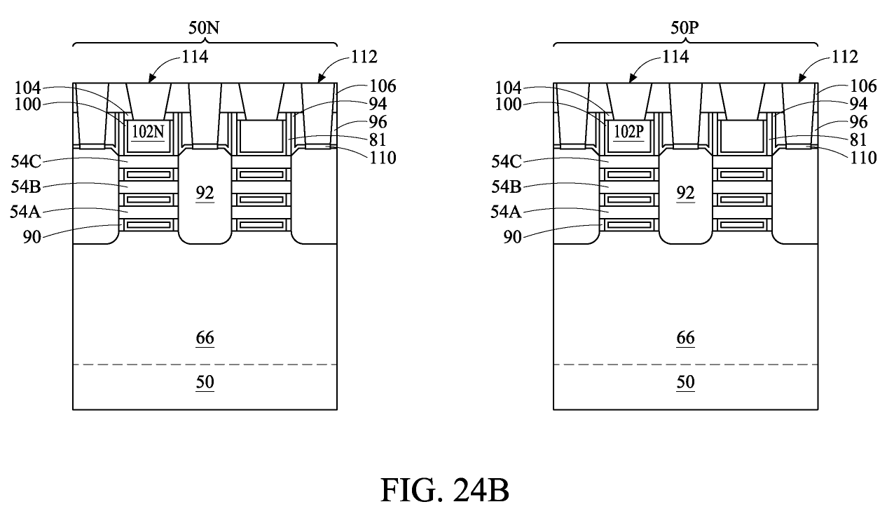

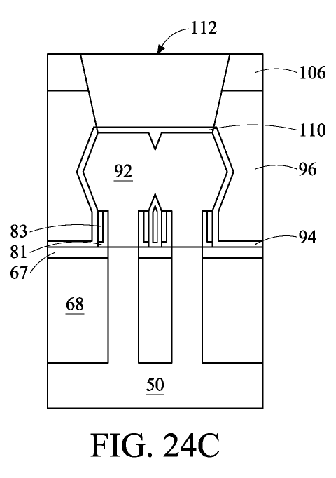

In still other embodiments, the first semiconductor layers 51 may be removed and the second semiconductor layers 53 may be patterned to form channel regions of nano-FETS in both the n-type region 50N and the p-type region 50P. In other embodiments, the second semiconductor layers 53 may be removed and the first semiconductor layers 51 may be patterned to form channel regions of nono-FETs in both the n-type region 50N and the p-type region 50P. In such embodiments, the channel regions in both the n-type region 50N and the p-type region 50P may have a same material composition (e.g., silicon, or the another semiconductor material) and be formed simultaneously. FIGS. 24A, 24B and 24C, illustrate a structure resulting from such embodiments where the channel regions in both the p-type region 50P and the n-type region 50N comprise silicon, for example.

The multi-layer stack 64 is illustrated as including three layers of each of the first semiconductor layers 51 and the second semiconductor layers 53 for illustrative purposes. In some embodiments, the multi-layer stack 64 may include any number of the first semiconductor layers 51 and the second semiconductor layers 53. Each of the layers of the multi-layer stack 64 may be epitaxially grown using a process such as chemical vapor deposition (CVD), atomic layer deposition (ALD), vapor phase epitaxy (VPE), molecular beam epitaxy (MBE), or the like. In various embodiments, the first semiconductor layers 51 may be formed of a first semiconductor material suitable for p-type nano-FETs, such as silicon germanium, or the like, and the second semiconductor layers 53 may be formed of a second semiconductor material suitable for n-type nano-FETs, such as silicon, silicon carbon, or the like. The multi-layer stack 64 is illustrated as having a bottommost semiconductor layer suitable for p-type nano-FETs for illustrative purposes. In some embodiments, multi-layer stack 64 may be formed such that the bottommost layer is a semiconductor layer suitable for n-type nano-FETs.

The first semiconductor materials and the second semiconductor materials may be materials having a high-etch selectivity to one another. As such, the first semiconductor layers 51 of the first semiconductor material may be removed without significantly removing the second semiconductor layers 53 of the second semiconductor material in the n-type region 50N, thereby allowing the second semiconductor layers 53 to be patterned to form channel regions of n-type nano-FETs. Similarly, the second semiconductor layers 53 of the second semiconductor material may be removed without significantly removing the first semiconductor layers 51 of the first semiconductor material in the p-type region 50P, thereby allowing the first semiconductor layers 51 to be patterned to form channel regions of p-type nano-FETs.

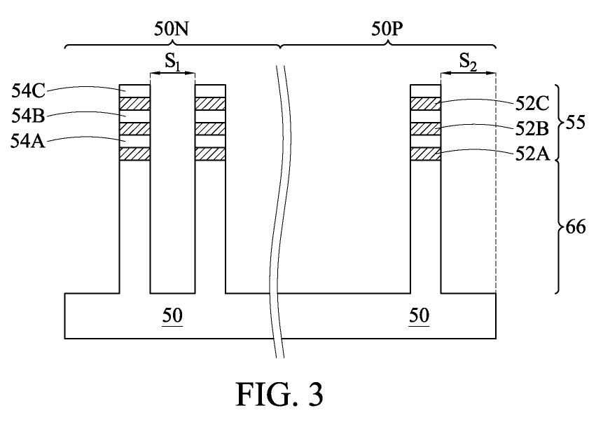

Referring now to FIG. 3, fins 66 are formed in the substrate 50 and nanostructures 55 are formed in the multi-layer stack 64, in accordance with some embodiments. In some embodiments, the nanostructures 55 and the fins 66 may be formed in the multi-layer stack 64 and the substrate 50, respectively, by etching trenches in the multi-layer stack 64 and the substrate 50. The etching may be any acceptable etch process, such as a reactive ion etch (RIE), neutral beam etch (NBE), the like, or a combination thereof. The etching may be anisotropic. Forming the nanostructures 55 by etching the multi-layer stack 64 may further define first nanostructures 52A-C (collectively referred to as the first nanostructures 52) from the first semiconductor layers 51 and define second nanostructures 54A-C (collectively referred to as the second nanostructures 54) from the second semiconductor layers 53. The first nanostructures 52 and the second nanostructures 54 may further be collectively referred to as nanostructures 55.

The fins 66 and the nanostructures 55 may be patterned by any suitable method. For example, the fins 66 and the nanostructures 55 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 66.

FIG. 3 further illustrates the fins 66 in the n-type region 50N and the p-type region 50P as having substantially equal widths for illustrative purposes. In some embodiments, widths of the fins 66 in the n-type region 50N may be greater or thinner than widths of the fins 66 in the p-type region 50P. Further, while each of the fins 66 and the nanostructures 55 are illustrated as having a consistent width throughout, in other embodiments, the fins 66 and/or the nanostructures 55 may have tapered sidewalls such that a width of each of the fins 66 and/or the nanostructures 55 continuously increases in a direction towards the substrate 50. In such embodiments, each of the nanostructures 55 may have a different width and be trapezoidal in shape.

Additionally, FIG. 3 illustrates that some of the nanostructures 55 may be arranged in a dense region (represented in FIG. 3 using the n-type region 50N, although it could also be the p-type region 50P or any other suitable region) where the nanostructures 55 are arranged close to each other. In a particular embodiment the nanostructures 55 within the n-type region 50N may be arranged so that there is a first spacing S₁ of between about 30 nm and about 50 nm, so that the nanostructures 55 have a first density. However, any suitable spacing may be utilized.

Other ones of the nanostructures are also arranged in a non-dense region (represented in FIG. 3 using the p-type region 50P, although it could also be the n-type region 50N or any other suitable region) where the nanostructures 55 are arranged farther apart from each other than in the dense region. In a particular embodiment the nanostructures 55 within the p-type region 50P may be arranged so that there is a second spacing S₂ (between the nanostructures illustrated in FIG. 3 and other nanostructures 55 not separately illustrated in FIG. 3) of between about 50 nm and about 200 nm, so that the nanostructures 55 have a second density less than the first density. However, any suitable spacing may be utilized.

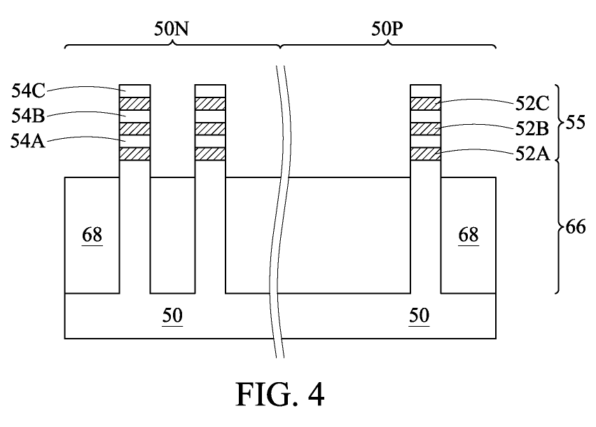

In FIG. 4, shallow trench isolation (STI) regions 68 are formed adjacent the fins 66. The STI regions 68 may be formed by depositing an insulation material over the substrate 50, the fins 66, and nanostructures 55, and between adjacent fins 66. The insulation material may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In the illustrated embodiment, the insulation material is silicon oxide formed by an FCVD process. An anneal process may be performed once the insulation material is formed. In an embodiment, the insulation material is formed such that excess insulation material covers the nanostructures 55. Although the insulation material is illustrated as a single layer, some embodiments may utilize multiple layers. For example, in some embodiments a liner (not separately illustrated) may first be formed along a surface of the substrate 50, the fins 66, and the nanostructures 55. Thereafter, a fill material, such as those discussed above may be formed over the liner.

A removal process is then applied to the insulation material to remove excess insulation material over the nanostructures 55. In some embodiments, a planarization process such as a chemical mechanical polish (CMP), an etch-back process, combinations thereof, or the like may be utilized. The planarization process exposes the nanostructures 55 such that top surfaces of the nanostructures 55 and the insulation material are level after the planarization process is complete.

The insulation material is then recessed to form the STI regions 68. The insulation material is recessed such that upper portions of fins 66 in the n-type region 50N and the p-type region 50P protrude from between neighboring STI regions 68. Further, the top surfaces of the STI regions 68 may have a flat surface as illustrated, a convex surface, a concave surface (such as dishing), or a combination thereof. The top surfaces of the STI regions 68 may be formed flat, convex, and/or concave by an appropriate etch. The STI regions 68 may be recessed using an acceptable etching process, such as one that is selective to the material of the insulation material (e.g., etches the material of the insulation material at a faster rate than the material of the fins 66 and the nanostructures 55). For example, an oxide removal using, for example, dilute hydrofluoric (dHF) acid may be used.

The process described above with respect to FIGS. 2-4 is just one example of how the fins 66 and the nanostructures 55 may be formed. In some embodiments, the fins 66 and/or the nanostructures 55 may be formed using a mask and an epitaxial growth process. For example, a dielectric layer can be formed over a top surface of the substrate 50, and trenches can be etched through the dielectric layer to expose the underlying substrate 50. Epitaxial structures can be epitaxially grown in the trenches, and the dielectric layer can be recessed such that the epitaxial structures protrude from the dielectric layer to form the fins 66 and/or the nanostructures 55. The epitaxial structures may comprise the alternating semiconductor materials discussed above, such as the first semiconductor materials and the second semiconductor materials. In some embodiments where epitaxial structures are epitaxially grown, the epitaxially grown materials may be in situ doped during growth, which may obviate prior and/or subsequent implantations, although in situ and implantation doping may be used together.

Additionally, the first semiconductor layers 51 (and resulting first nanostructures 52) and the second semiconductor layers 53 (and resulting second nanostructures 54) are illustrated and discussed herein as comprising the same materials in the p-type region 50P and the n-type region 50N for illustrative purposes only. As such, in some embodiments one or both of the first semiconductor layers 51 and the second semiconductor layers 53 may be different materials or formed in a different order in the p-type region 50P and the n-type region 50N.

Further in FIG. 4, appropriate wells (not separately illustrated) may be formed in the fins 66, the nanostructures 55, and/or the STI regions 68. In embodiments with different well types, different implant steps for the n-type region 50N and the p-type region 50P may be achieved using a photoresist or other masks (not separately illustrated). For example, a photoresist may be formed over the fins 66 and the STI regions 68 in the n-type region 50N and the p-type region 50P. The photoresist is patterned to expose the p-type region 50P. The photoresist can be formed by using a spin-on technique and can be patterned using acceptable photolithography techniques. Once the photoresist is patterned, an n-type impurity implant is performed in the p-type region 50P, and the photoresist may act as a mask to substantially prevent n-type impurities from being implanted into the n-type region 50N. The n-type impurities may be phosphorus, arsenic, antimony, or the like implanted in the region to a concentration in a range from about 10¹³ atoms/cm³ to about 10¹⁴ atoms/cm³. After the implant, the photoresist is removed, such as by an acceptable ashing process.

Following or prior to the implanting of the p-type region 50P, a photoresist or other masks (not separately illustrated) is formed over the fins 66, the nanostructures 55, and the STI regions 68 in the p-type region 50P and the n-type region 50N. The photoresist is patterned to expose the n-type region 50N. The photoresist can be formed by using a spin-on technique and can be patterned using acceptable photolithography techniques. Once the photoresist is patterned, a p-type impurity implant may be performed in the n-type region 50N, and the photoresist may act as a mask to substantially prevent p-type impurities from being implanted into the p-type region 50P. The p-type impurities may be boron, boron fluoride, indium, or the like implanted in the region to a concentration in a range from about 10¹³ atoms/cm³ to about 10¹⁴ atoms/cm³. After the implant, the photoresist may be removed, such as by an acceptable ashing process.

After the implants of the n-type region 50N and the p-type region 50P, an anneal may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

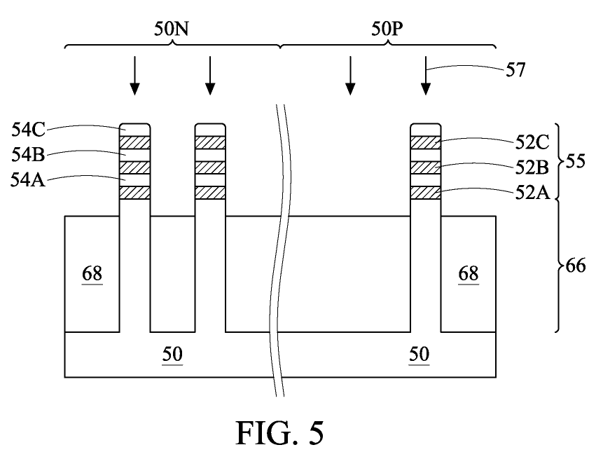

In FIG. 5, a rounding process (represented in FIG. 5 by the arrows labeled 57) is utilized in order to trim the topmost second nanostructures 54C and round the corners and edges. In an embodiment the rounding process 57 is one or more etching processes, such as one or more wet or dry etching processes, such as an anisotropic wet etch process that works to remove material from both the top surface of the topmost second nanostructures 54C as well as side surfaces of the topmost second nanostructures 54C. However, any suitable trimming process may be utilized.

In an embodiment the one or more wet or dry etching processes may remove material from the top and corner of the topmost second nanostructures 54C in order to round the topmost second nanostructures 54C. In a particular embodiment between about 1 nm and about 2 nm may be removed of material from the top of the topmost second nanostructures 54C. Additionally, the one or more wet or dry etching processes may remove between about 0.5 nm and about 1.5 nm or greater of material from the corner of the topmost second nanostructures 54C, either in the horizontal direction in FIG. 5 or the vertical direction in FIG. 5.

By using the rounding process 57, the corners of the openings between the nanostructures 55 also become more rounded. As such, materials such as subsequently used precursors can more readily and easily enter into and exit out of the openings between the nanostructures 55 without being blocked by the sharp corners. Such improvements, as discussed further below, helps alleviate the loading between different regions over the substrate 50.

In FIG. 6, a first dielectric layer 62 is deposited between the nanostructures 55 and over the STI regions 68. In an embodiment the first dielectric layer 62 may be a dielectric material such as silicon nitride, silicon carbide, silicon carbide nitride, combinations of these, or the like, deposited using a deposition process such as chemical vapor deposition, atomic layer deposition, combinations of these, or the like. However, any suitable materials and deposition processes may be utilized.

Unfortunately, during the deposition process the different spacings (e.g., the differences between the first spacing S₁ and the second spacing S₂) between the nanostructures 55 in the dense region (e.g., the first spacing S₁) and between the nanostructures 55 in the non-dense region (e.g., the second spacing S₂) will impact the deposition process differently in the dense region (e.g., the n-type region 50N) and the non-dense region (e.g., the p-type region 50P). In particular, the different spacings will impact the ability of the precursors to get into the bottom of the trenches between the nanostructures 55. Such an impact will lead to differences in how much of the material in the first dielectric layer 62 is deposited between the nanostructures 55 in the different regions.

However, by rounding the corners of the nanostructures 55 as described above with respect to FIG. 5, the impact that the nanostructures 55 has on the deposition process can be reduced. In particular, by rounding the corners of the openings between the nanostructures 55, the openings are enlarged along the top surfaces, and the first dielectric layer 62 can be deposited more conformally than if the nanostructures 55 remain unrounded. As such, the first dielectric layer 62 may be deposited within the dense region (e.g., the n-type region 50N) to a first thickness T₁ of between about 5 nm and about 30 nm, while the same process may deposit the first dielectric layer 62 within the non-dense region (e.g., the p-type region 50P) to a second thickness T₂ of between about 5 nm and about 30 nm, which is larger than the first thickness T₁. However, any suitable thicknesses may be utilized.

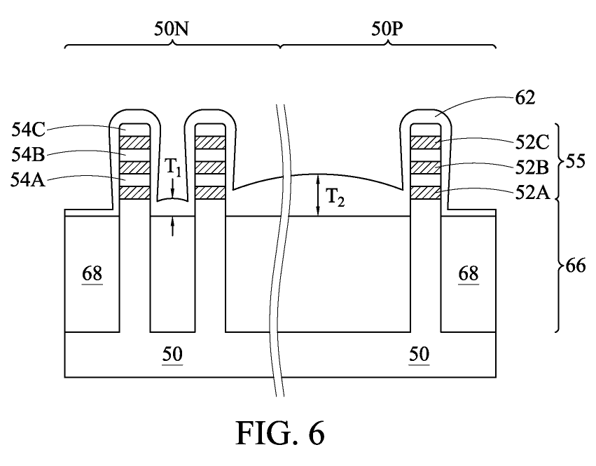

FIG. 7 illustrates formation of an STI hardmask 67 from the first dielectric layer 62 by reducing the thicknesses of the first dielectric layer 62 (e.g., the first thickness T₁ and the second thickness T₂). In an embodiment the STI hardmask 67 may be formed using one or more wet or dry etching processes, or a combination of dry and wet etching processes. Any suitable combination of removal processes may be utilized.

However, because the first dielectric layer 62 begins the reduction process with different thicknesses (e.g., the first thickness T₁ and the second thickness T₂), the reduction process that forms the STI hardmask 67 from the first dielectric layer 62 will also have different thicknesses within the dense region (e.g., the n-type region 50N) and the non-dense region (e.g., the p-type region 50P). In a particular embodiment the STI hardmask 67 in the dense region (e.g., the n-type region 50N) may have a third thickness T₃ of between about 5 nm and about 15 nm, while the STI hardmask 67 in the non-dense region (e.g., the p-type region 50P) may have a fourth thickness T₄ of between about 5 nm and about 15 nm. However, any suitable thicknesses may be utilized.

By utilizing the rounding process 57 discussed above with respect to FIG. 5, the differences between the third thickness T₃ and the fourth thickness T₄ can be reduced. In particular, the loading between the dense region (e.g., the n-type region 50N) and the non-dense region (e.g., the p-type region 50P) can be reduced to be less than about 6.6 nm. However, any suitable loading may be utilized.

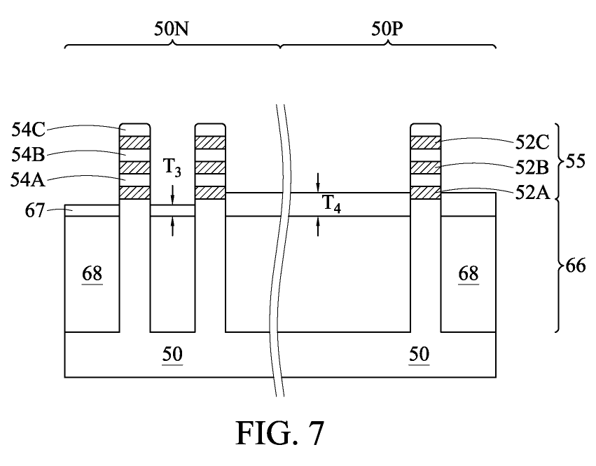

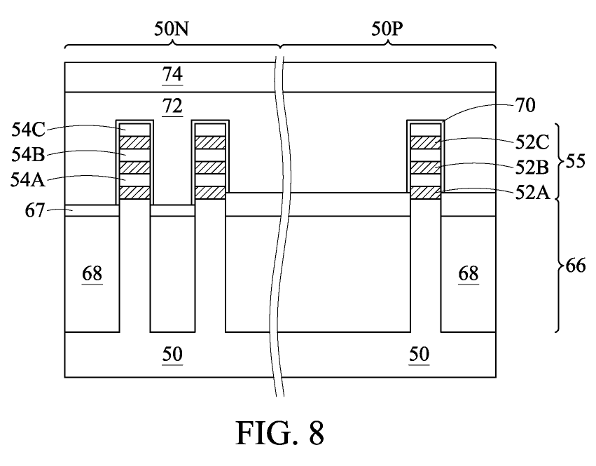

In FIG. 8, a dummy dielectric layer 70 is formed over the STI hardmask 67, on the fins 66, and/or the nanostructures 55. The dummy dielectric layer 70 may be, for example, silicon oxide, silicon nitride, a combination thereof, or the like, and may be deposited or thermally grown according to acceptable techniques. A dummy gate layer 72 is formed over the dummy dielectric layer 70, and a mask layer 74 is formed over the dummy gate layer 72. The dummy gate layer 72 may be deposited over the dummy dielectric layer 70 and then planarized, such as by a CMP. The mask layer 74 may be deposited over the dummy gate layer 72. The dummy gate layer 72 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer 72 may be deposited by physical vapor deposition (PVD), CVD, sputter deposition, or other techniques for depositing the selected material. The dummy gate layer 72 may be made of other materials that have a high etching selectivity from the etching of isolation regions. The mask layer 74 may include, for example, silicon nitride, silicon oxynitride, or the like. In this example, a single dummy gate layer 72 and a single mask layer 74 are formed across the n-type region 50N and the p-type region 50P. It is noted that the dummy dielectric layer 70 is shown covering only the fins 66 and the nanostructures 55 for illustrative purposes only. In some embodiments, the dummy dielectric layer 70 may be deposited such that the dummy dielectric layer 70 covers the STI regions 68, such that the dummy dielectric layer 70 extends between the dummy gate layer 72 and the STI regions 68.

FIGS. 9A-23C illustrate various additional steps in the manufacturing of embodiment devices. FIGS. 9A, 10A, 11A, 12A, 13A, 14A, 15A, 15C, 16A, 16C, 17A, 18A, 21C, 22C and 23C illustrate features in either the regions 50N or the regions 50P. In FIGS. 9A and 9B, the mask layer 74 may be patterned using acceptable photolithography and etching techniques to form masks 78. The pattern of the masks 78 then may be transferred to the dummy gate layer 72 and to the dummy dielectric layer 70 to form dummy gates 76 and dummy gate dielectrics 71, respectively. The dummy gates 76 cover respective channel regions of the fins 66. The pattern of the masks 78 may be used to physically separate each of the dummy gates 76 from adjacent dummy gates 76. The dummy gates 76 may also have a lengthwise direction substantially perpendicular to the lengthwise direction of respective fins 66.

In FIGS. 10A and 10B, a first spacer layer 80 and a second spacer layer 82 are formed over the structures illustrated in FIGS. 9A and 9B, respectively. The first spacer layer 80 and the second spacer layer 82 will be subsequently patterned to act as spacers for forming self-aligned source/drain regions. In FIGS. 10A and 10B, the first spacer layer 80 is formed on top surfaces of the STI regions 68; top surfaces and sidewalls of the fins 66, the nanostructures 55, and the masks 78; and sidewalls of the dummy gates 76 and the dummy gate dielectric 71. The second spacer layer 82 is deposited over the first spacer layer 80. The first spacer layer 80 may be formed of silicon oxide, silicon nitride, silicon oxynitride, or the like, using techniques such as thermal oxidation or deposited by CVD, ALD, or the like. The second spacer layer 82 may be formed of a material having a different etch rate than the material of the first spacer layer 80, such as silicon oxide, silicon nitride, silicon oxynitride, or the like, and may be deposited by CVD, ALD, or the like.

After the first spacer layer 80 is formed and prior to forming the second spacer layer 82, implants for lightly doped source/drain (LDD) regions (not separately illustrated) may be performed. In embodiments with different device types, similar to the implants discussed above in FIG. 4, a mask, such as a photoresist, may be formed over the n-type region 50N, while exposing the p-type region 50P, and appropriate type (e.g., p-type) impurities may be implanted into the exposed fins 66 and nanostructures 55 in the p-type region 50P. The mask may then be removed. Subsequently, a mask, such as a photoresist, may be formed over the p-type region 50P while exposing the n-type region 50N, and appropriate type impurities (e.g., n-type) may be implanted into the exposed fins 66 and nanostructures 55 in the n-type region 50N. The mask may then be removed. The n-type impurities may be the any of the n-type impurities previously discussed, and the p-type impurities may be the any of the p-type impurities previously discussed. The lightly doped source/drain regions may have a concentration of impurities in a range from about 1x10¹⁵ atoms/cm³ to about 1x10¹⁹ atoms/cm³. An anneal may be used to repair implant damage and to activate the implanted impurities.

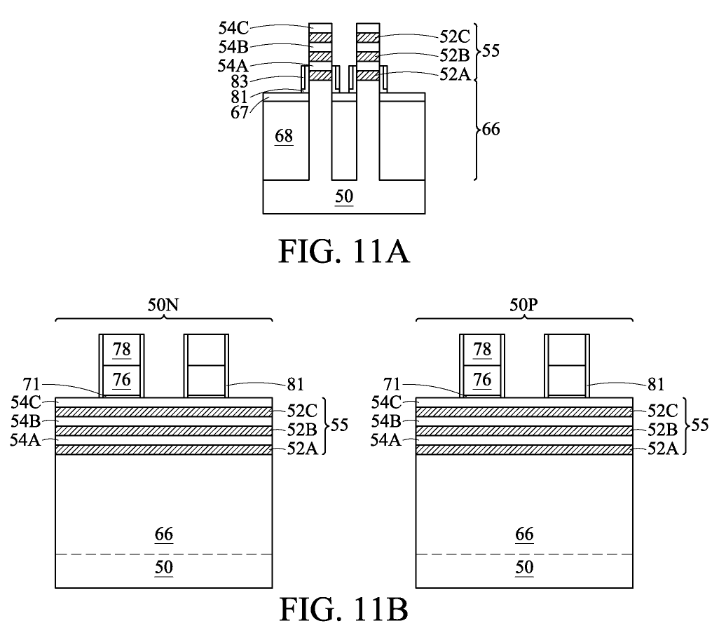

In FIGS. 11A and 11B, the first spacer layer 80 and the second spacer layer 82 are etched to form first spacers 81 and second spacers 83. As will be discussed in greater detail below, the first spacers 81 and the second spacers 83 act to self-align subsequently formed source drain regions, as well as to protect sidewalls of the fins 66 and/or nanostructure 55 during subsequent processing. The first spacer layer 80 and the second spacer layer 82 may be etched using a suitable etching process, such as an isotropic etching process (e.g., a wet etching process), an anisotropic etching process (e.g., a dry etching process), or the like. In some embodiments, the material of the second spacer layer 82 has a different etch rate than the material of the first spacer layer 80, such that the first spacer layer 80 may act as an etch stop layer when patterning the second spacer layer 82 and such that the second spacer layer 82 may act as a mask when patterning the first spacer layer 80. For example, the second spacer layer 82 may be etched using an anisotropic etch process wherein the first spacer layer 80 acts as an etch stop layer, wherein remaining portions of the second spacer layer 82 form second spacers 83 as illustrated in FIG. 11A. Thereafter, the second spacers 83 acts as a mask while etching exposed portions of the first spacer layer 80, thereby forming first spacers 81 as illustrated in FIG. 11A.

As illustrated in FIG. 11A, the first spacers 81 and the second spacers 83 are disposed on sidewalls of the fins 66 and/or nanostructures 55. As illustrated in FIG. 11B, in some embodiments, the second spacer layer 82 may be removed from over the first spacer layer 80 adjacent the masks 78, the dummy gates 76, and the dummy gate dielectrics 71, and the first spacers 81 are disposed on sidewalls of the masks 78, the dummy gates 76, and the dummy dielectric layers 70. In other embodiments, a portion of the second spacer layer 82 may remain over the first spacer layer 80 adjacent the masks 78, the dummy gates 76, and the dummy gate dielectrics 71.

It is noted that the above disclosure generally describes a process of forming spacers and LDD regions. Other processes and sequences may be used. For example, fewer or additional spacers may be utilized, different sequence of steps may be utilized (e.g., the first spacers 81 may be patterned prior to depositing the second spacer layer 82), additional spacers may be formed and removed, and/or the like. Furthermore, the n-type and p-type devices may be formed using different structures and steps.

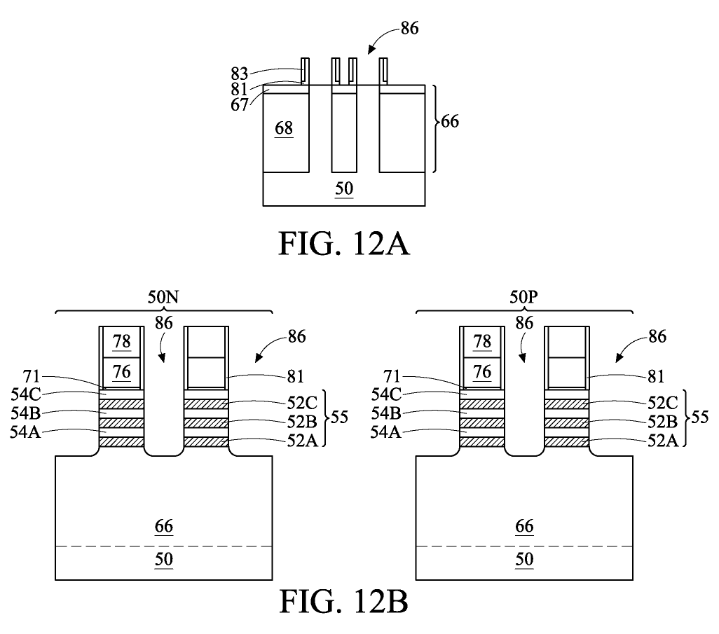

In FIGS. 12A and 12B, first recesses 86 are formed in the fins 66, the nanostructures 55, and the substrate 50, in accordance with some embodiments. Epitaxial source/drain regions will be subsequently formed in the first recesses 86. The first recesses 86 may extend through the first nanostructures 52 and the second nanostructures 54, and into the substrate 50. As illustrated in FIG. 12A, top surfaces of the STI hardmask 67 may be level with bottom surfaces of the first recesses 86. In various embodiments, the fins 66 may be etched such that bottom surfaces of the first recesses 86 are disposed below the top surfaces of the STI hardmask 67; or the like. The first recesses 86 may be formed by etching the fins 66, the nanostructures 55, and the substrate 50 using anisotropic etching processes, such as RIE, NBE, or the like. The first spacers 81, the second spacers 83, and the masks 78 mask portions of the fins 66, the nanostructures 55, and the substrate 50 during the etching processes used to form the first recesses 86. A single etch process or multiple etch processes may be used to etch each layer of the nanostructures 55 and/or the fins 66. Timed etch processes may be used to stop the etching of the first recesses 86 after the first recesses 86 reach a desired depth.

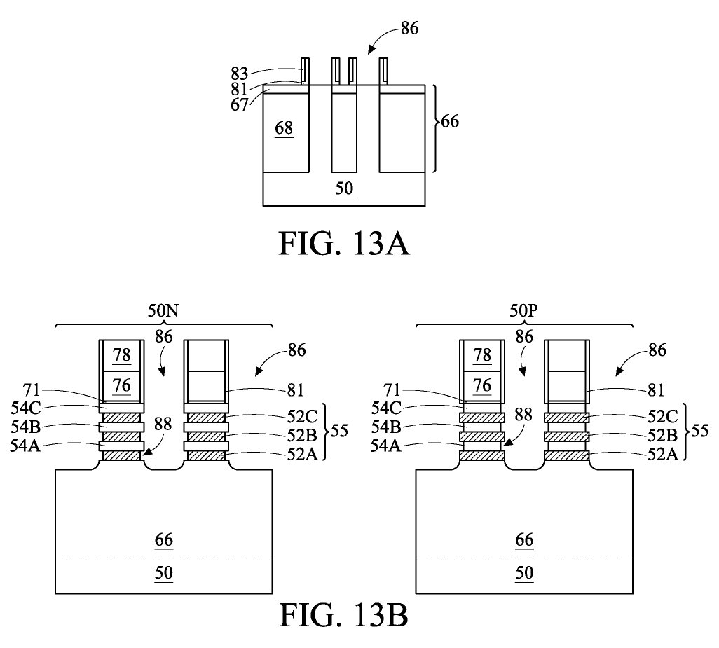

In FIGS. 13A and 13B, portions of sidewalls of the layers of the multi-layer stack 64 formed of the first semiconductor materials (e.g., the first nanostructures 52) exposed by the first recesses 86 are etched to form sidewall recesses 88 in the n-type region 50N, and portions of sidewalls of the layers of the multi-layer stack 64 formed of the second semiconductor materials (e.g., the second nanostructures 54) exposed by the first recesses 86 are etched to form sidewall recesses 88 in the p-type region 50P. Although sidewalls of the first nanostructures 52 and the second nanostructures 54 in sidewall recesses 88 are illustrated as being straight in FIG. 13B, the sidewalls may be concave or convex. The sidewalls may be etched using isotropic etching processes, such as wet etching or the like. The p-type region 50P may be protected using a mask (not shown) while etchants selective to the first semiconductor materials are used to etch the first nanostructures 52 such that the second nanostructures 54 and the substrate 50 remain relatively unetched as compared to the first nanostructures 52 in the n-type region 50N. Similarly, the n-type region 50N may be protected using a mask (not shown) while etchants selective to the second semiconductor materials are used to etch the second nanostructures 54 such that the first nanostructures 52 and the substrate 50 remain relatively unetched as compared to the second nanostructures 54 in the p-type region 50P. In an embodiment in which the first nanostructures 52 include, e.g., SiGe, and the second nanostructures 54 include, e.g., Si or SiC, a dry etch process with tetramethylammonium hydroxide (TMAH), ammonium hydroxide (NH₄OH), or the like may be used to etch sidewalls of the first nanostructures 52 in the n-type region 50N, and a wet or dry etch process with hydrogen fluoride, another fluorine-based etchant, or the like may be used to etch sidewalls of the second nanostructures 54 in the p-type region 50P.

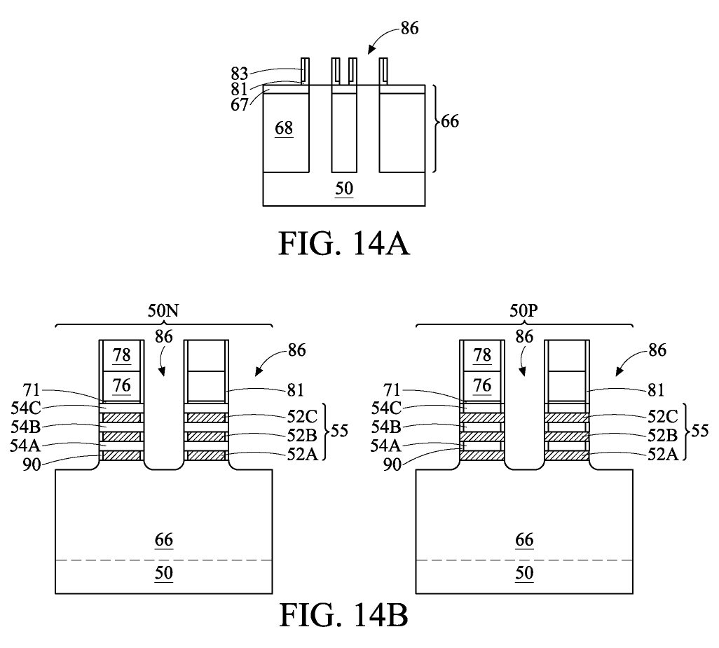

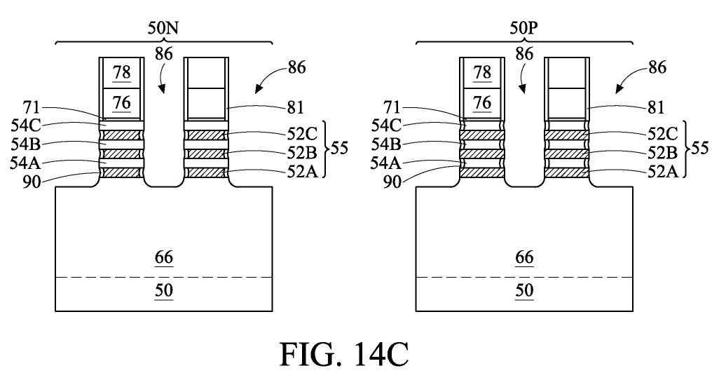

In FIGS. 14A-14C, first inner spacers 90 are formed in the sidewall recess 88. The first inner spacers 90 may be formed by depositing an inner spacer layer (not separately illustrated) over the structures illustrated in FIGS. 13A and 13B. The first inner spacers 90 act as isolation features between subsequently formed source/drain regions and a gate structure. As will be discussed in greater detail below, source/drain regions will be formed in the first recesses 86, while the first nanostructures 52 in the n-type region 50N and the second nanostructures 54 in the p-type region 50P will be replaced with corresponding gate structures.

The inner spacer layer may be deposited by a conformal deposition process, such as CVD, ALD, or the like. The inner spacer layer may comprise a material such as silicon nitride or silicon oxynitride, although any suitable material, such as low-dielectric constant (low-k) materials having a k-value less than about 3.5, may be utilized. The inner spacer layer may then be anisotropically etched to form the first inner spacers 90. Although outer sidewalls of the first inner spacers 90 are illustrated as being flush with sidewalls of the second nanostructures 54 in the n-type region 50N and flush with the sidewalls of the first nanostructures 52 in the p-type region 50P, the outer sidewalls of the first inner spacers 90 may extend beyond or be recessed from sidewalls of the second nanostructures 54 and/or the first nanostructures 52, respectively.

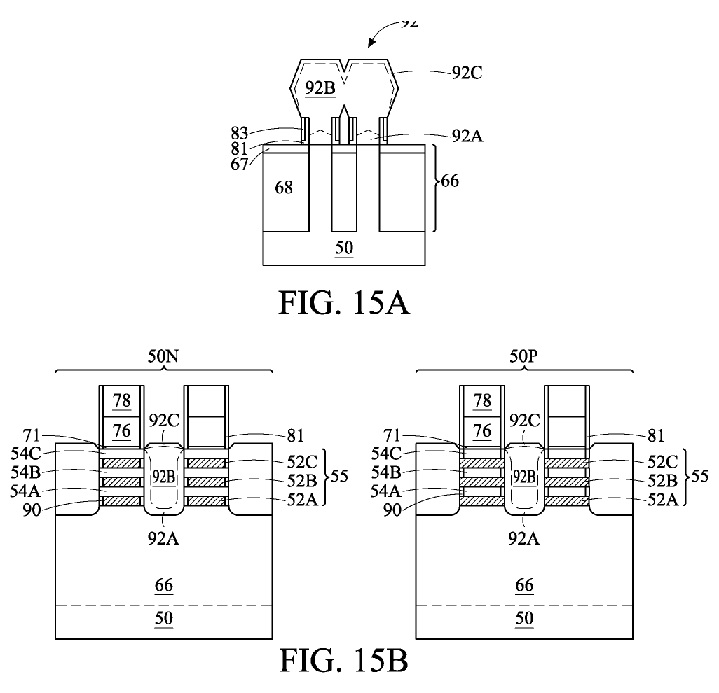

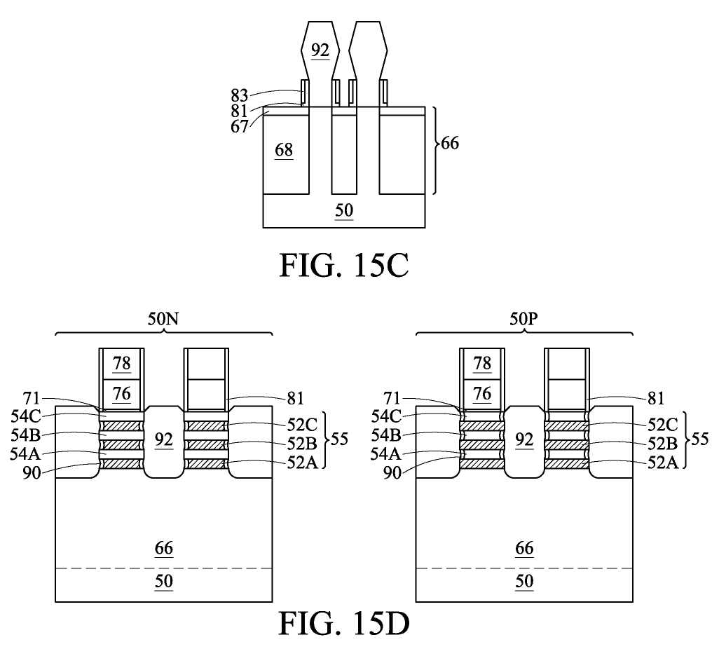

Moreover, although the outer sidewalls of the first inner spacers 90 are illustrated as being straight in FIG. 14B, the outer sidewalls of the first inner spacers 90 may be concave or convex. As an example, FIG. 14C illustrates an embodiment in which sidewalls of the first nanostructures 52 are concave, outer sidewalls of the first inner spacers 90 are concave, and the first inner spacers 90 are recessed from sidewalls of the second nanostructures 54 in the n-type region 50N. Also illustrated are embodiments in which sidewalls of the second nanostructures 54 are concave, outer sidewalls of the first inner spacers 90 are concave, and the first inner spacers 90 are recessed from sidewalls of the first nanostructures 52 in the p-type region 50P. The inner spacer layer may be etched by an anisotropic etching process, such as RIE, NBE, or the like. The first inner spacers 90 may be used to prevent damage to subsequently formed source/drain regions (such as the epitaxial source/drain regions 92, discussed below with respect to FIGS. 15A-15C) by subsequent etching processes, such as etching processes used to form gate structures.

In FIGS. 15A-15C, epitaxial source/drain regions 92 are formed in the first recesses 86. In some embodiments, the epitaxial source/drain regions 92 may exert stress on the second nanostructures 54 in the n-type region 50N and on the first nanostructures 52 in the p-type region 50P, thereby improving performance. As illustrated in FIG. 15B, the epitaxial source/drain regions 92 are formed in the first recesses 86 such that each dummy gate 76 is disposed between respective neighboring pairs of the epitaxial source/drain regions 92. In some embodiments, the first spacers 81 are used to separate the epitaxial source/drain regions 92 from the dummy gates 76 and the first inner spacers 90 are used to separate the epitaxial source/drain regions 92 from the nanostructures 55 by an appropriate lateral distance so that the epitaxial source/drain regions 92 do not short out with subsequently formed gates of the resulting nano-FETs.

The epitaxial source/drain regions 92 in the n-type region 50N, e.g., the NMOS region, may be formed by masking the p-type region 50P, e.g., the PMOS region. Then, the epitaxial source/drain regions 92 are epitaxially grown in the first recesses 86 in the n-type region 50N. The epitaxial source/drain regions 92 may include any acceptable material appropriate for n-type nano-FETs. For example, if the second nanostructures 54 are silicon, the epitaxial source/drain regions 92 may include materials exerting a tensile strain on the second nanostructures 54, such as silicon, silicon carbide, phosphorous doped silicon carbide, silicon phosphide, or the like. The epitaxial source/drain regions 92 may have surfaces raised from respective upper surfaces of the nanostructures 55 and may have facets.

The epitaxial source/drain regions 92 in the p-type region 50P, e.g., the PMOS region, may be formed by masking the n-type region 50N, e.g., the NMOS region. Then, the epitaxial source/drain regions 92 are epitaxially grown in the first recesses 86 in the p-type region 50P. The epitaxial source/drain regions 92 may include any acceptable material appropriate for p-type nano-FETs. For example, if the first nanostructures 52 are silicon germanium, the epitaxial source/drain regions 92 may comprise materials exerting a compressive strain on the first nanostructures 52, such as silicon-germanium, boron doped silicon-germanium, germanium, germanium tin, or the like. The epitaxial source/drain regions 92 may also have surfaces raised from respective surfaces of the multi-layer stack 64 and may have facets.

The epitaxial source/drain regions 92, the first nanostructures 52, the second nanostructures 54, and/or the substrate 50 may be implanted with dopants to form source/drain regions, similar to the process previously discussed for forming lightly-doped source/drain regions, followed by an anneal. The source/drain regions may have an impurity concentration of between about 1x10¹⁹ atoms/cm³ and about 1x10²¹ atoms/cm³. The n-type and/or p-type impurities for source/drain regions may be any of the impurities previously discussed. In some embodiments, the epitaxial source/drain regions 92 may be in situ doped during growth.

As a result of the epitaxy processes used to form the epitaxial source/drain regions 92 in the n-type region 50N and the p-type region 50P, upper surfaces of the epitaxial source/drain regions 92 have facets which expand laterally outward beyond sidewalls of the nanostructures 55. In some embodiments, these facets cause adjacent epitaxial source/drain regions 92 of a same nano-FET to merge as illustrated by FIG. 15A. In other embodiments, adjacent epitaxial source/drain regions 92 remain separated after the epitaxy process is completed as illustrated by FIG. 15C. In the embodiments illustrated in FIGS. 15A and 15C, the first spacers 81 may be formed to a top surface of the STI hardmask 67 thereby blocking the epitaxial growth. In some other embodiments, the first spacers 81 may cover portions of the sidewalls of the nanostructures 55 further blocking the epitaxial growth. In some other embodiments, the spacer etch used to form the first spacers 81 may be adjusted to remove the spacer material to allow the epitaxially grown region to extend to the surface of the STI hardmask 67.

The epitaxial source/drain regions 92 may comprise one or more semiconductor material layers. For example, the epitaxial source/drain regions 92 may comprise a first semiconductor material layer 92A, a second semiconductor material layer 92B, and a third semiconductor material layer 92C. Any number of semiconductor material layers may be used for the epitaxial source/drain regions 92. Each of the first semiconductor material layer 92A, the second semiconductor material layer 92B, and the third semiconductor material layer 92C may be formed of different semiconductor materials and may be doped to different dopant concentrations. In some embodiments, the first semiconductor material layer 92A may have a dopant concentration less than the second semiconductor material layer 92B and greater than the third semiconductor material layer 92C. In embodiments in which the epitaxial source/drain regions 92 comprise three semiconductor material layers, the first semiconductor material layer 92A may be deposited, the second semiconductor material layer 92B may be deposited over the first semiconductor material layer 92A, and the third semiconductor material layer 92C may be deposited over the second semiconductor material layer 92B.

FIG. 15D illustrates an embodiment in which sidewalls of the first nanostructures 52 in the n-type region 50N and sidewalls of the second nanostructures 54 in the p-type region 50P are concave, outer sidewalls of the first inner spacers 90 are concave, and the first inner spacers 90 are recessed from sidewalls of the second nanostructures 54 and the first nanostructures 52, respectively. As illustrated in FIG. 15D, the epitaxial source/drain regions 92 may be formed in contact with the first inner spacers 90 and may extend past sidewalls of the second nanostructures 54 in the n-type region 50N and past sidewalls of the first nanostructures 52 in the p-type region 50P.

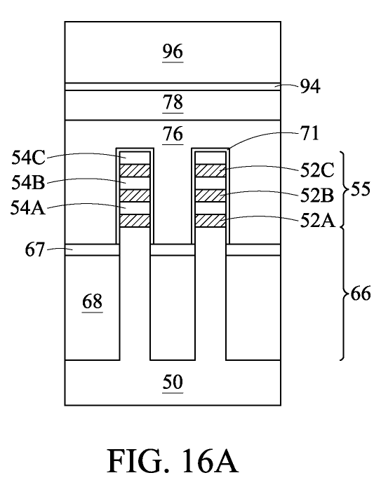

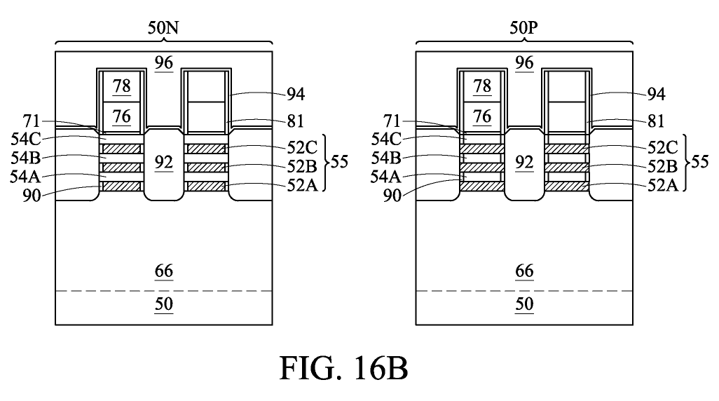

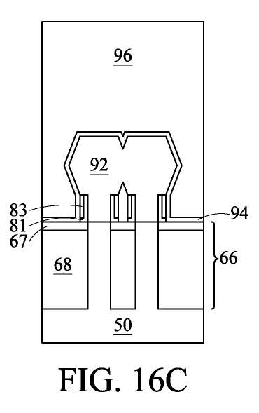

In FIGS. 16A-16C, a first interlayer dielectric (ILD) 96 is deposited over the structure illustrated in FIGS. 9A, 15B and 15A, (the processes of FIGS. 10A-15D do not alter the cross-section illustrated in FIGS. 9A), respectively. The first ILD 96 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) 94 is disposed between the first ILD 96 and the epitaxial source/drain regions 92, the masks 78, and the first spacers 81. The CESL 94 may comprise a dielectric material, such as, silicon nitride, silicon oxide, silicon oxynitride, or the like, having a different etch rate than the material of the overlying first ILD 96.

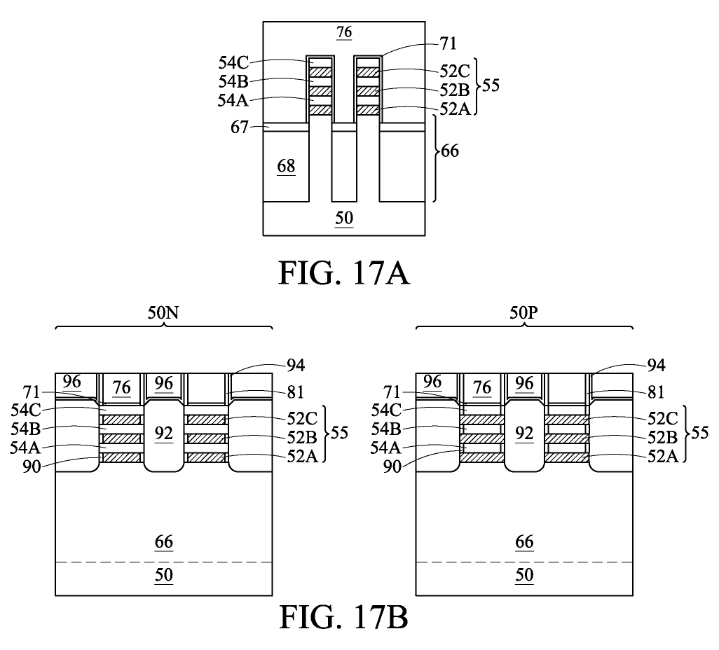

In FIGS. 17A-17B, a planarization process, such as a CMP, may be performed to level the top surface of the first ILD 96 with the top surfaces of the dummy gates 76 or the masks 78. The planarization process may also remove the masks 78 on the dummy gates 76, and portions of the first spacers 81 along sidewalls of the masks 78. After the planarization process, top surfaces of the dummy gates 76, the first spacers 81, and the first ILD 96 are level within process variations. Accordingly, the top surfaces of the dummy gates 76 are exposed through the first ILD 96. In some embodiments, the masks 78 may remain, in which case the planarization process levels the top surface of the first ILD 96 with top surface of the masks 78 and the first spacers 81.

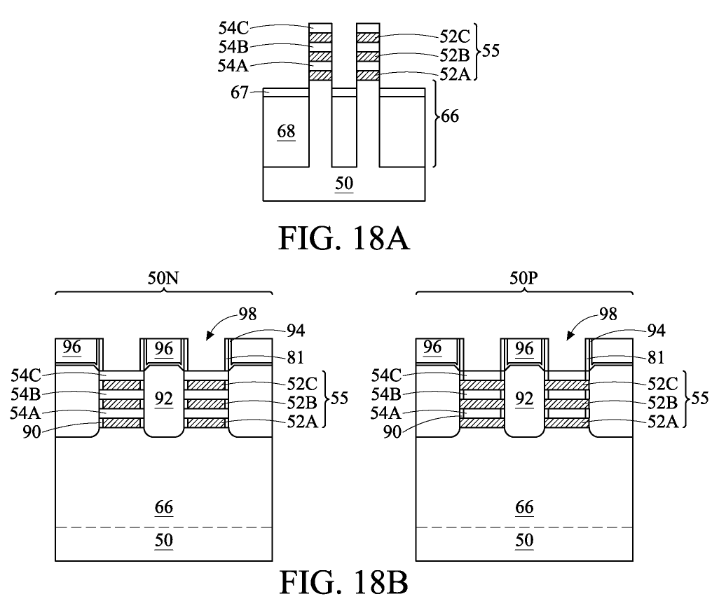

In FIGS. 18A and 18B, the dummy gates 76, and the masks 78 if present, are removed in one or more etching steps, so that second recesses 98 are formed. Portions of the dummy dielectric layers 70 in the second recesses 98 are also be removed. In some embodiments, the dummy gates 76 and the dummy dielectric layers 70 are removed by an anisotropic dry etch process. For example, the etching process may include a dry etch process using reaction gas(es) that selectively etch the dummy gates 76 at a faster rate than the first ILD 96 or the first spacers 81. Each second recess 98 exposes and/or overlies portions of nanostructures 55, which act as channel regions in subsequently completed nano-FETs. Portions of the nanostructures 55 which act as the channel regions are disposed between neighboring pairs of the epitaxial source/drain regions 92. During the removal, the dummy dielectric layers 60 may be used as etch stop layers when the dummy gates 76 are etched. The dummy dielectric layers 70 may then be removed after the removal of the dummy gates 76.

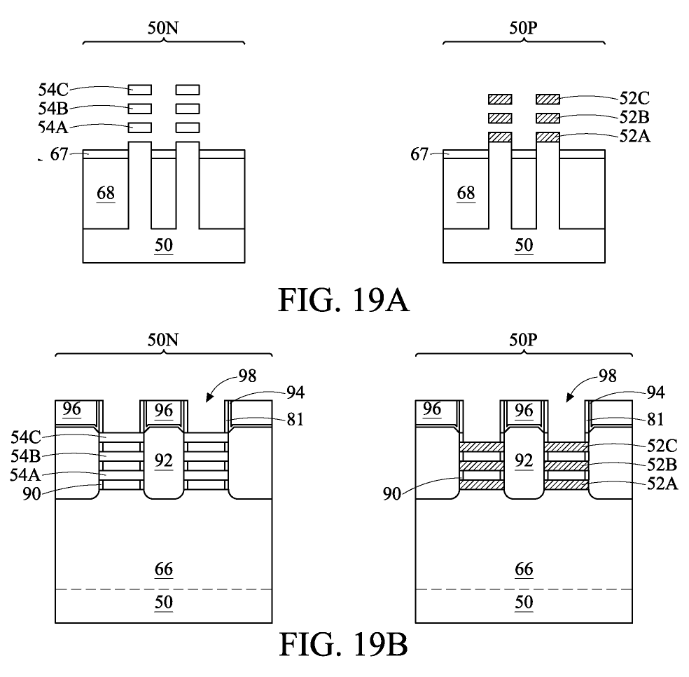

In FIGS. 19A and 19B, the first nanostructures 52 in the n-type region 50N and the second nanostructures 54 in the p-type region 50P are removed extending the second recesses 98. The first nanostructures 52 may be removed by forming a mask (not shown) over the p-type region 50P and performing an isotropic etching process such as wet etching or the like using etchants which are selective to the materials of the first nanostructures 52, while the second nanostructures 54, the substrate 50, the STI hardmask 67, and the STI regions 68 remain relatively unetched as compared to the first nanostructures 52. In embodiments in which the first nanostructures 52 include, e.g., SiGe, and the second nanostructures 54A-54C include, e.g., Si or SiC, tetramethylammonium hydroxide (TMAH), ammonium hydroxide (NH₄OH), or the like may be used to remove the first nanostructures 52 in the n-type region 50N.

The second nanostructures 54 in the p-type region 50P may be removed by forming a mask (not shown) over the n-type region 50N and performing an isotropic etching process such as wet etching or the like using etchants which are selective to the materials of the second nanostructures 54, while the first nanostructures 52, the substrate 50, the STI hardmask 67, and the STI regions 68 remain relatively unetched as compared to the second nanostructures 54. In embodiments in which the second nanostructures 54 include, e.g., SiGe, and the first nanostructures 52 include, e.g., Si or SiC, hydrogen fluoride, another fluorine-based etchant, or the like may be used to remove the second nanostructures 54 in the p-type region 50P.

In other embodiments, the channel regions in the n-type region 50N and the p-type region 50P may be formed simultaneously, for example by removing the first nanostructures 52 in both the n-type region 50N and the p-type region 50P or by removing the second nanostructures 54 in both the n-type region 50N and the p-type region 50P. In such embodiments, channel regions of n-type nano-FETs and p-type nano-FETS may have a same material composition, such as silicon, silicon germanium, or the like. FIGS. 24A, 24B and 24C, illustrate a structure resulting from such embodiments where the channel regions in both the p-type region 50P and the n-type region 50N are provided by the second nanostructures 54 and comprise silicon, for example.

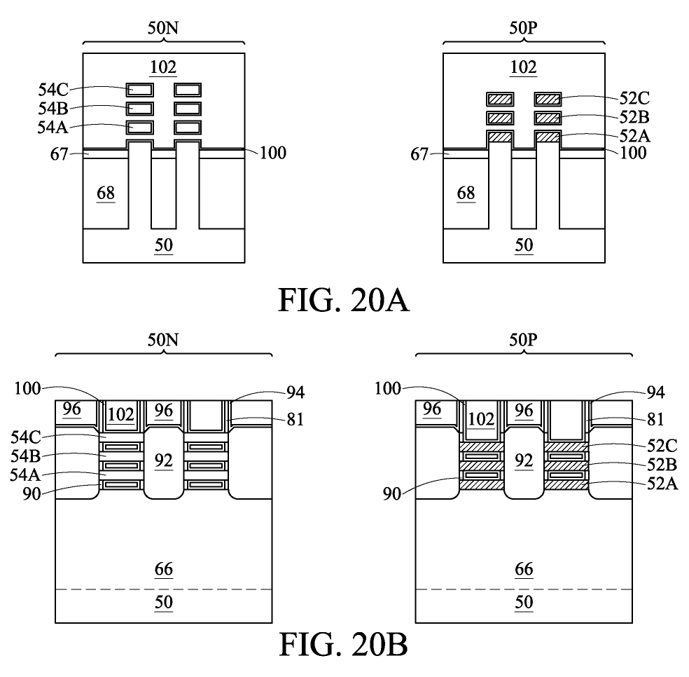

In FIGS. 20A and 20B, gate dielectric layers 100 and gate electrodes 102 are formed for replacement gates. The gate dielectric layers 100 are deposited conformally in the second recesses 98. In the n-type region 50N, the gate dielectric layers 100 may be formed on top surfaces and sidewalls of the substrate 50 and on top surfaces, sidewalls, and bottom surfaces of the second nanostructures 54, and in the p-type region 50P, the gate dielectric layers 100 may be formed on top surfaces and sidewalls of the substrate 50 and on top surfaces, sidewalls, and bottom surfaces of the first nanostructures 52. The gate dielectric layers 100 may also be deposited on top surfaces of the first ILD 96, the CESL 94, the first spacers 81, the STI hardmask 67, and the STI regions 68.

In accordance with some embodiments, the gate dielectric layers 100 comprise one or more dielectric layers, such as an oxide, a metal oxide, the like, or combinations thereof. For example, in some embodiments, the gate dielectric layers 100 may comprise a silicon oxide layer and a metal oxide layer over the silicon oxide layer. In some embodiments, the gate dielectric layers 100 include a high-k dielectric material, and in these embodiments, the gate dielectric layers 100 may have a k value greater than about 7.0, and may include a metal oxide or a silicate of hafnium, aluminum, zirconium, lanthanum, manganese, barium, titanium, lead, and combinations thereof. The structure of the gate dielectric layers 100 may be the same or different in the n-type region 50N and the p-type region 50P. The formation methods of the gate dielectric layers 100 may include molecular-beam deposition (MBD), ALD, PECVD, and the like.

The gate electrodes 102 are deposited over the gate dielectric layers 100, respectively, and fill the remaining portions of the second recesses 98. The gate electrodes 102 may include a metal-containing material such as titanium nitride, titanium oxide, tantalum nitride, tantalum carbide, cobalt, ruthenium, aluminum, tungsten, combinations thereof, or multi-layers thereof. For example, although single layer gate electrodes 102 are illustrated in FIGS. 20A and 20B, the gate electrodes 102 may comprise any number of liner layers, any number of work function tuning layers, and a fill material. Any combination of the layers which make up the gate electrodes 102 may be deposited in the n-type region 50N between adjacent ones of the second nanostructures 54 and between the second nanostructure 54A and the substrate 50, and may be deposited in the p-type region 50P between adjacent ones of the first nanostructures 52.

The formation of the gate dielectric layers 100 in the n-type region 50N and the p-type region 50P may occur simultaneously such that the gate dielectric layers 100 in each region are formed from the same materials, and the formation of the gate electrodes 102 may occur simultaneously such that the gate electrodes 102 in each region are formed from the same materials. In some embodiments, the gate dielectric layers 100 in each region may be formed by distinct processes, such that the gate dielectric layers 100 may be different materials and/or have a different number of layers, and/or the gate electrodes 102 in each region may be formed by distinct processes, such that the gate electrodes 102 may be different materials and/or have a different number of layers. Various masking steps may be used to mask and expose appropriate regions when using distinct processes.

After the filling of the second recesses 98, a planarization process, such as a CMP, may be performed to remove the excess portions of the gate dielectric layers 100 and the material of the gate electrodes 102, which excess portions are over the top surface of the first ILD 96. The remaining portions of material of the gate electrodes 102 and the gate dielectric layers 100 thus form replacement gate structures of the resulting nano-FETs. The gate electrodes 102 and the gate dielectric layers 100 may be collectively referred to as “gate structures.”

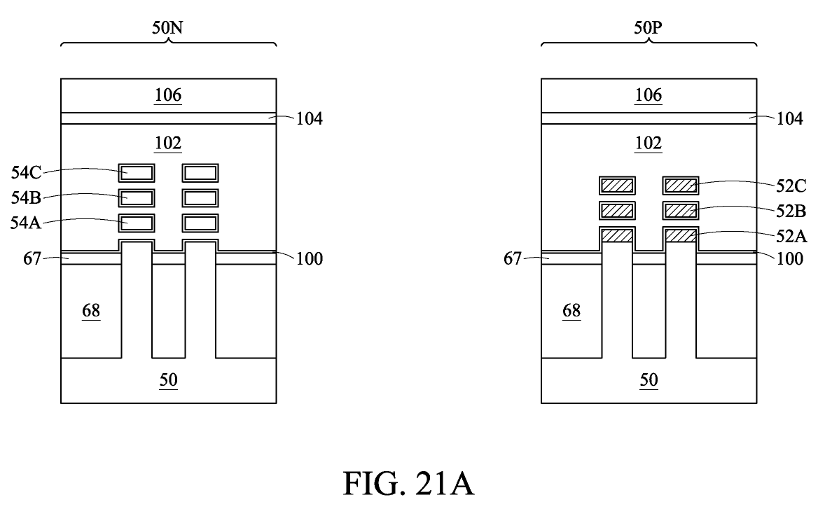

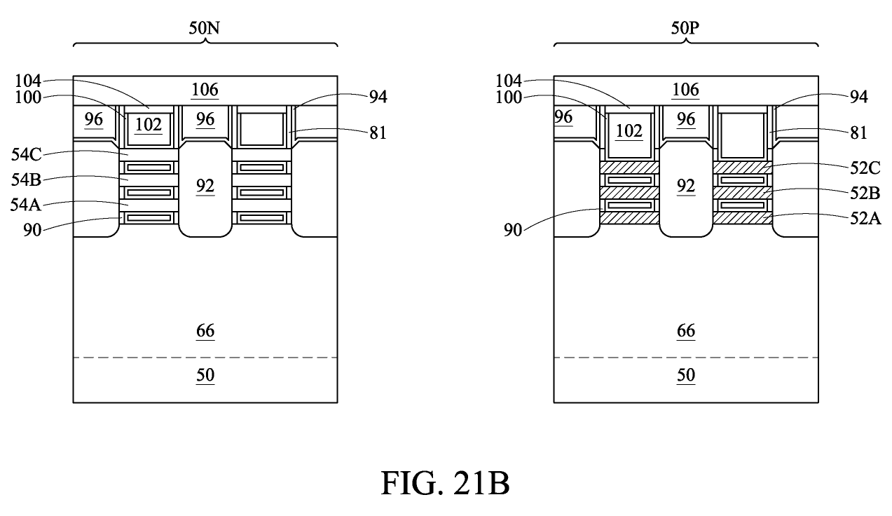

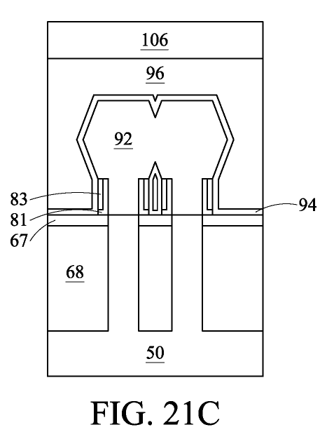

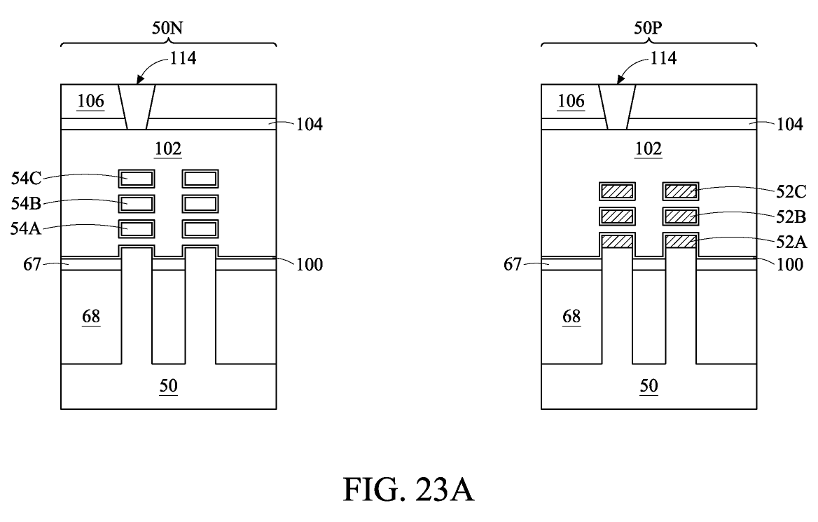

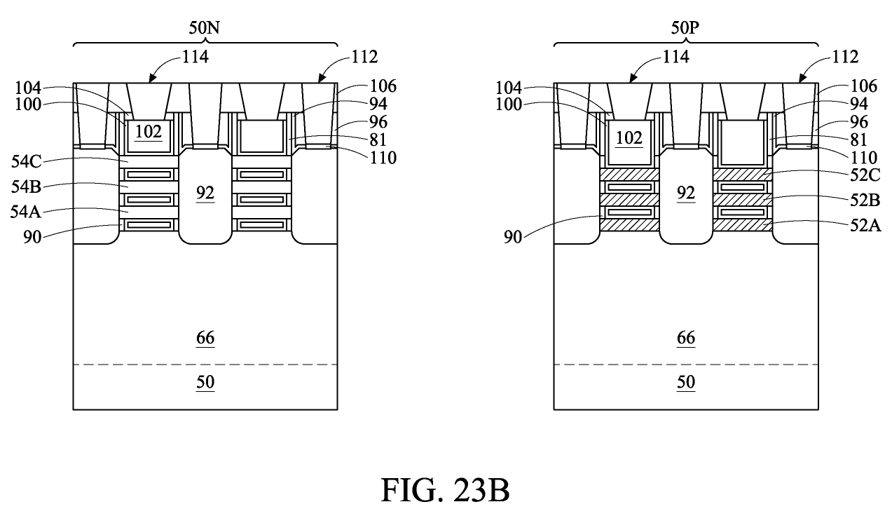

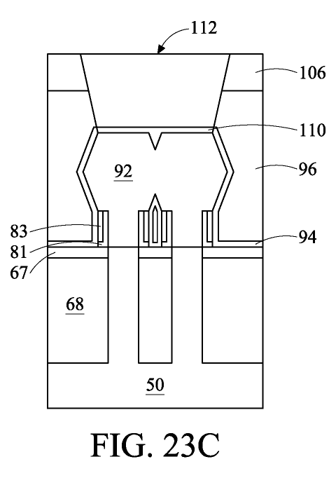

In FIGS. 21A-21C, the gate structure (including the gate dielectric layers 100 and the corresponding overlying gate electrodes 102) is recessed, so that a recess is formed directly over the gate structure and between opposing portions of first spacers 81. A gate mask 104 comprising one or more layers of dielectric material, such as silicon nitride, silicon oxynitride, or the like, is filled in the recess, followed by a planarization process to remove excess portions of the dielectric material extending over the first ILD 96. Subsequently formed gate contacts (such as the gate contacts 114, discussed below with respect to FIGS. 23A-23C) penetrate through the gate mask 104 to contact the top surface of the recessed gate electrodes 102.

As further illustrated by FIGS. 21A-21C, a second ILD 106 is deposited over the first ILD 96 and over the gate mask 104. In some embodiments, the second ILD 106 is a flowable film formed by FCVD. In some embodiments, the second ILD 106 is formed of a dielectric material such as PSG, BSG, BPSG, USG, or the like, and may be deposited by any suitable method, such as CVD, PECVD, or the like.

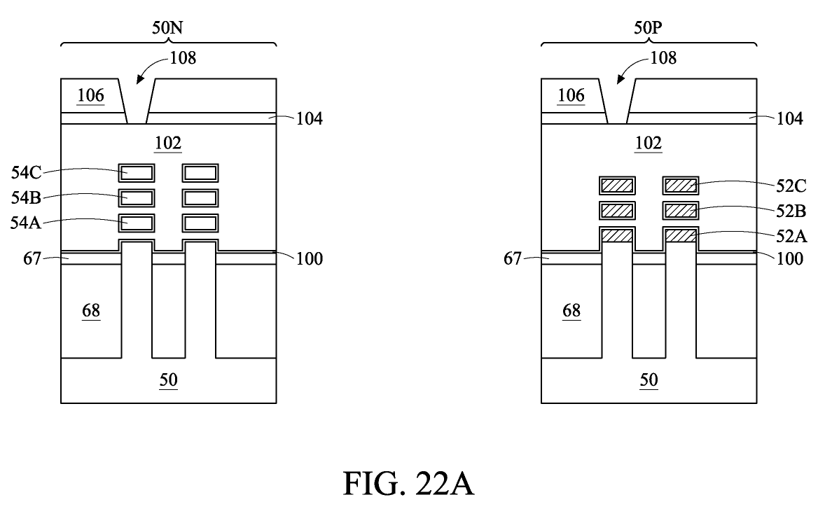

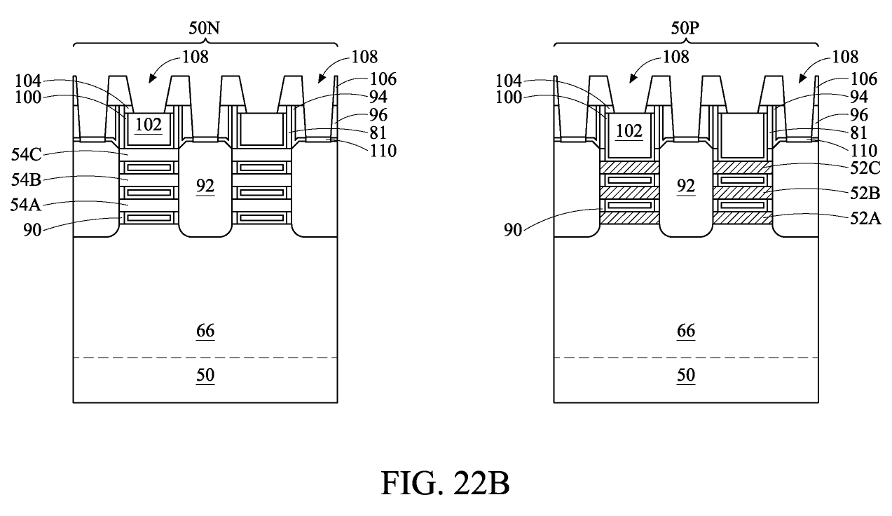

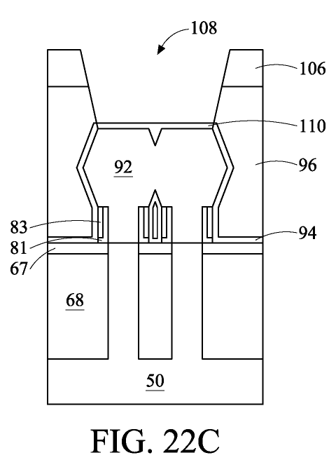

In FIGS. 22A-22C, the second ILD 106, the first ILD 96, the CESL 94, and the gate masks 104 are etched to form third recesses 108 exposing surfaces of the epitaxial source/drain regions 92 and/or the gate structure. The third recesses 108 may be formed by etching using an anisotropic etching process, such as RIE, NBE, or the like. In some embodiments, the third recesses 108 may be etched through the second ILD 106 and the first ILD 96 using a first etching process; may be etched through the gate masks 104 using a second etching process; and may then be etched through the CESL 94 using a third etching process. A mask, such as a photoresist, may be formed and patterned over the second ILD 106 to mask portions of the second ILD 106 from the first etching process and the second etching process. In some embodiments, the etching process may over-etch, and therefore, the third recesses 108 extend into the epitaxial source/drain regions 92 and/or the gate structure, and a bottom of the third recesses 108 may be level with (e.g., at a same level, or having a same distance from the substrate), or lower than (e.g., closer to the substrate) the epitaxial source/drain regions 92 and/or the gate structure. Although FIGS. 22A-22C illustrate the third recesses 108 as exposing the epitaxial source/drain regions 92 and the gate structure in a same cross section, in various embodiments, the epitaxial source/drain regions 92 and the gate structure may be exposed in different cross-sections, thereby reducing the risk of shorting subsequently formed contacts. After the third recesses 108 are formed, silicide regions 110 are formed over the epitaxial source/drain regions 92. In some embodiments, the silicide regions 110 are formed by first depositing a metal (not shown) capable of reacting with the semiconductor materials of the underlying epitaxial source/drain regions 92 (e.g., silicon, silicon germanium, germanium) to form silicide or germanide regions, such as nickel, cobalt, titanium, tantalum, platinum, tungsten, other noble metals, other refractory metals, rare earth metals or their alloys, over the exposed portions of the epitaxial source/drain regions 92, then performing a thermal anneal process to form the silicide regions 110. The un-reacted portions of the deposited metal are then removed, e.g., by an etching process. Although silicide regions 110 are referred to as silicide regions, silicide regions 110 may also be germanide regions, or silicon germanide regions (e.g., regions comprising silicide and germanide). In an embodiment, the silicide region 110 comprises TiSi, and has a thickness in a range between about 2 nm and about 10 nm.

Next, in FIGS. 23A-23C, contacts 112 and 114 (may also be referred to as contact plugs) are formed in the third recesses 108. The contacts 112 and 114 may each comprise one or more layers, such as barrier layers, diffusion layers, and fill materials. For example, in some embodiments, the contacts 112 and 114 each include a barrier layer and a conductive material, and is electrically coupled to the underlying conductive feature (e.g., gate electrode 102 and/or silicide region 110 in the illustrated embodiment). The contacts 114 are electrically coupled to the gate electrode 102 and may be referred to as gate contacts, and the contacts 112 are electrically coupled to the silicide regions 110 and may be referred to as source/drain contacts. The barrier layer may include titanium, titanium nitride, tantalum, tantalum nitride, or the like. The conductive material may be copper, a copper alloy, silver, gold, tungsten, cobalt, aluminum, nickel, or the like. A planarization process, such as a CMP, may be performed to remove excess material from a surface of the second ILD 106.

Additionally, at this point in the process, the sheet width of the topmost second nanostructures 54C may have a smaller width than the fins 66. In particular, the various processes used to form the structures illustrated in FIGS. 23A-23C may consume exposed structures such as the topmost second nanostructures 54C may be consumed, while other structures such as the fins 66 remain protected by the STI region 68 and the STI hardmask 67. In particular embodiments, the width of the fins 66 minus the sheet width of the topmost second nanostructures 54C may be greater than about 1.5 nm. However, any suitable difference may be utilized.

FIGS. 24A-24C illustrate cross-sectional views of a device according to some alternative embodiments. FIGS. 24A illustrates reference cross-section A-A’ illustrated in FIG. 1. FIG. 24B illustrates reference cross-section B-B’ illustrated in FIG. 1. FIG. 24C illustrates reference cross-section C-C’ illustrated in FIG. 1. In FIGS. 24A-24C, like reference numerals indicate like elements formed by like processes as the structure of FIGS. 23A-23C. However, in FIGS. 24A-24C, channel regions in the n-type region 50N and the p-type region 50P comprise a same material. For example, the second nanostructures 54, which comprise silicon, provide channel regions for p-type nano-FETs in the p-type region 50P and for n-type nano-FETs in the n-type region 50N. The structure of FIGS. 24A-24C may be formed, for example, by removing the first nanostructures 52 from both the p-type region 50P and the n-type region 50N simultaneously; depositing the gate dielectric layers 100 and the gate electrodes 102P (e.g., gate electrode suitable for a p-type nano-FET) around the second nanostructures 54 in the p-type region 50P; and depositing the gate dielectric layers 100 and the gate electrodes 102N (e.g., a gate electrode suitable for a n-type nano-FET) around the second nanostructures 54 in the n-type region 50N. In such embodiments, materials of the epitaxial source/drain regions 92 may be different in the n-type region 50N compared to the p-type region 50P as explained above.

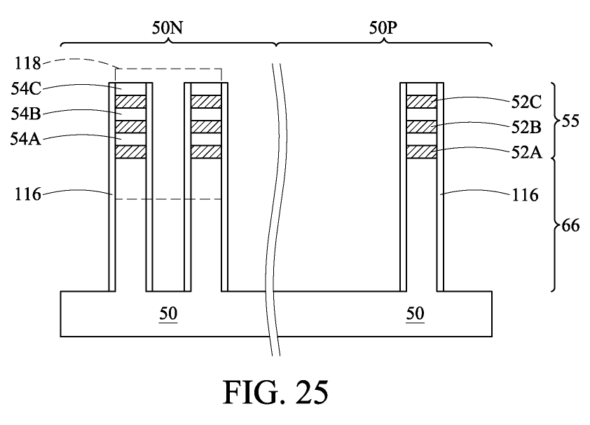

FIG. 25 illustrates yet another embodiment in which the nanostructures 55 are rounded in order to help reduce the loading, and where a liner 116 is located along a sidewall of the fins 66 and the nanostructures 55. In the embodiment illustrated in FIG. 25, the process as illustrated in FIGS. 2-4 as described above is utilized, and the liner 116 is deposited over the nanostructures 55. In a particular embodiment the liner 116 comprises a material such as silicon, silicon nitride, silicon oxide, combinations of these, or the like, and is deposited using a deposition process such as chemical vapor deposition, epitaxial growth, atomic layer deposition, combinations of these, or the like. The liner 116 may be deposited to a thickness of between about 2 nm and about 3 nm. Once the material of the liner 116 has been deposited, horizontal portions of the liner 116 over the nanostructures 55 may be removed using, e.g., an etching process. However, any suitable material, process, and thickness may be utilized.

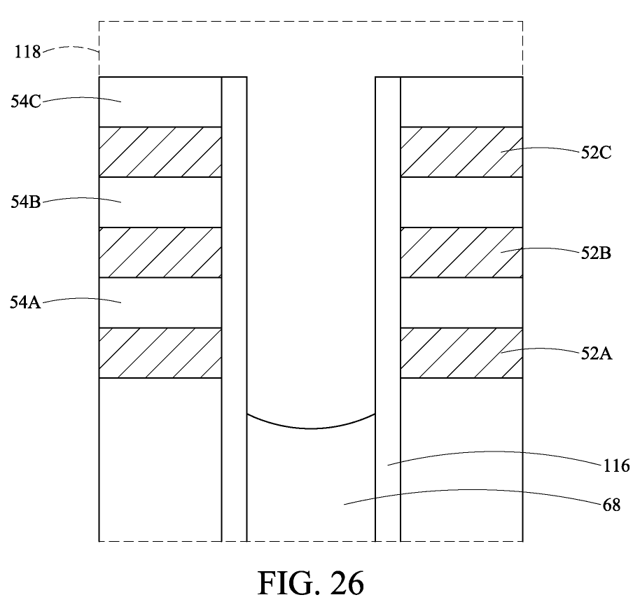

FIG. 26 illustrates a close-up view of the dashed box labeled 118 in FIG. 25 after the STI regions 68 has been formed. In an embodiment the STI regions 68 may be formed as described above with respect to FIG. 4, such as depositing the material for the STI regions 68, planarizing the material, and recessing the material to form the STI regions 68. However, any suitable materials and processes may be utilized.

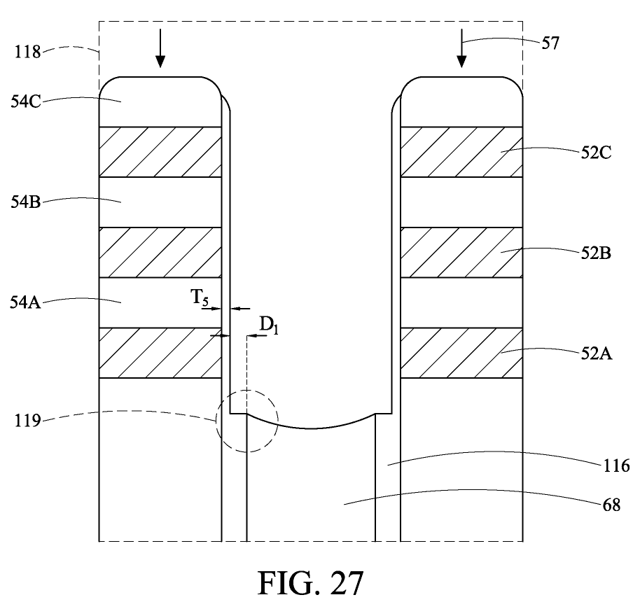

FIG. 27 illustrates the close-up view of the dashed box 118 after the rounding process 57 has rounded the top layer of the nanostructures 55. In an embodiment the rounding process 57 may be performed as described above with respect to FIG. 5, such as an anisotropic wet etch process. However, any suitable reduction process may be utilized.

However, in this embodiment, in addition to etching away material from the nanostructures 55, the rounding process 57 will additionally etch away material from the exposed portions of the liner 116. In some embodiments the rounding process 57 may remove a first distance D₁ of between about 0.5 nm and about 1.5 nm of material, thereby leaving the liner 116 having a fifth thickness T₅ of between about 0.5 nm and about 1.5 nm of material of the exposed portions of the liner 116, and also forming a platform (circled by the dashed line labeled 119) of the liner 116 adjacent to the STI region 68. However, any suitable amount of material, including a removal of all of the exposed material, may be removed, and all amount of removal is fully included in the scope of the embodiments.

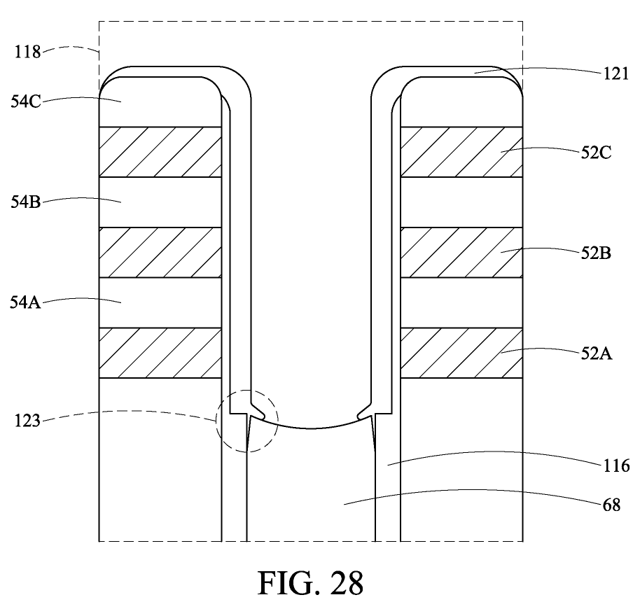

FIG. 28 illustrates that, once the rounding process 57 has been performed, a cap 121 may be formed over the nanostructures 55 and the exposed portions of the liner 116. In an embodiment the cap 121 may be semiconductor material such as silicon formed using an epitaxial growth process. However, any suitable material and any suitable deposition or growth process may be utilized.

However, because the growth process is an epitaxial growth process, the cap 121 will grow on the exposed liner 116 but will not grow on the STI regions 68, thereby leaving a majority of the STI regions 68 exposed. However, because the growth process will grow on multiple surfaces of the liner 116 at the platform (see FIG. 27), the cap 121 will form a protrusion (circled by the dashed line labeled 123) that extends at least partially over the STI regions 68. However, any suitable shapes may be formed.

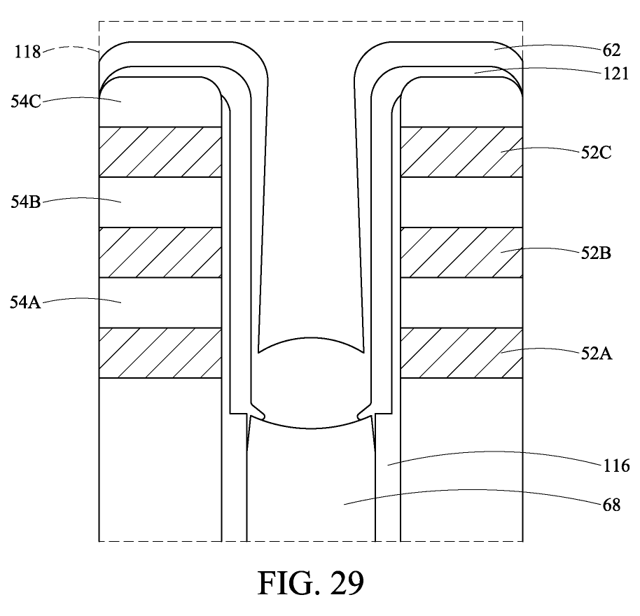

FIG. 29 illustrates that, once the cap 121 has been formed, the first dielectric layer 62 may be deposited. In an embodiment the first dielectric layer 62 may be formed as described above with respect to FIG. 6, such as by deposition of a material such as silicon nitride using a deposition process such as chemical vapor deposition or atomic layer deposition. However, any suitable material and method may be utilized.

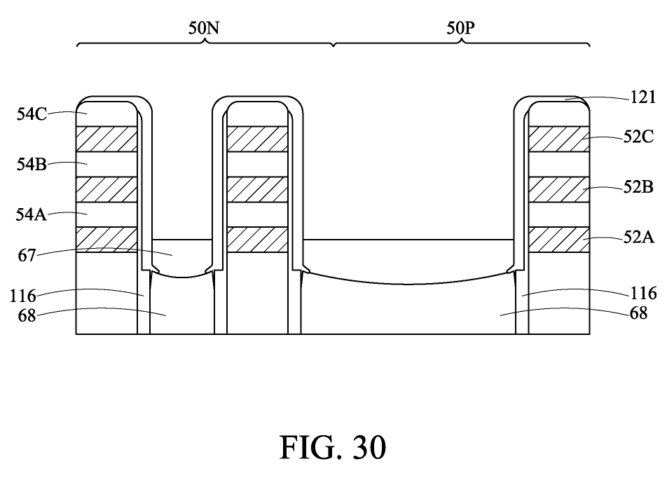

FIG. 30 illustrates that, once the first dielectric layer 62 has been deposited, the STI hardmask 67 is formed by reducing the material of the first dielectric layer 62. In an embodiment the STI hardmask 67 is formed using a combination of one or more dry and/or wet etching processes. However, any suitable processes or combination of processes may be utilized.

Additionally, while not explicitly illustrated in FIG. 30, once the STI hardmask 67 has been formed, a remainder of the processes discussed above can be utilized. In particular, the first nanostructures 52 are formed, the second nanostructures 54 are formed, and the gate electrodes 102 (along with other structures) are formed. However, any suitable structures and any suitable processes may be utilized.

By utilizing the STI hardmask 67 with the liner 116 and the cap 121, the thickness loading between the dense region (e.g., the n-type region 50N) and the non-dense region (e.g., the p-type region 50P) can be reduced and improved. In a particular embodiment, for an oxide definition space (OD space) of between about 35 nm and 83 nm, the thickness loading may be improved from 7.9 nm to 6.6 nm or less, for an overall improvement of 1.3 nm.

As such, by utilizing the embodiments described herein, a gap-fill friendly fin structure for the nanostructures 55 can be formed to help improve (e.g., reduce) the thickness loading of the STI hardmask 67 formed on the STI region 68 between dense regions and non-dense regions, such that the thicknesses of the bottom STI hardmask 67 formed in the dense regions and the non-dense regions will be more consistent. Further, by improving the thickness loading, the mesa height of the STI hardmask 67 can be reduced. Such a reduction in the mesa height can further improve the gain RO%.

In an embodiment, a method of manufacturing a semiconductor device includes: forming a multi-layer stack over a semiconductor substrate; patterning the multi-layer stack into a plurality of fins, the fins being located in a first region and a second region, the first region being a denser region than the second region; rounding corners of the plurality of fins; depositing a first dielectric between the fins; removing a portion of the first dielectric to form a first mask; and forming a gate structure over the first mask. In an embodiment the rounding the corners removes between about 0.5 nm and about 1.5 nm of material from at least one of the corners. In an embodiment the rounding the corners removes between about 1 nm and about 2 nm of material from a top surface of at least one of the fins. In an embodiment the rounding the corners removes material from a silicon liner in physical contact with one of the plurality of fins. In an embodiment the rounding the corners removes between about 0.5 nm and about 1.5 nm of material from the silicon liner. In an embodiment the method further includes growing a cap layer on exposed surfaces of the silicon liner and the plurality of fins. In an embodiment the growing the cap layer forms a protrusion that extends over an isolation region.

In another embodiment, a method of manufacturing a semiconductor device includes: forming an isolation region between fins over a semiconductor substrate, each of the fins comprising alternating layers of material; depositing a first dielectric material over the isolation region, the first dielectric material having a first thickness in a first region and a second thickness in a second region, the first thickness being different from the second thickness; and reducing the first thickness to a third thickness and reducing the second thickness to a fourth thickness, wherein after the reducing a loading between the first region and the second region is greater than zero and no larger than 6.6 nm. In an embodiment the method further includes, between the forming the isolation region and the depositing the first dielectric material, rounding corners of the fins. In an embodiment the rounding the corners of the fins removes between about 0.5 nm and about 1.5 nm of material from at least one of the corners. In an embodiment the rounding the corners further removes material from a silicon liner adjacent to one of the fins. In an embodiment the rounding the corners removes between about 0.5 nm and about 1.5 nm of the silicon liner. In an embodiment the method further includes, prior to the depositing the first dielectric material, forming a silicon cap. In an embodiment the silicon cap comprises a protrusion extending over the isolation region.

In yet another embodiment, a semiconductor device includes: a metal gate over a semiconductor substrate, the metal gate surrounding at least some of a plurality of nanostructures extending between a first source/drain region and a second source/drain region; an isolation region located between the metal gate and the semiconductor substrate; a mask layer located between the metal gate and the isolation region, the mask layer including: a first portion with a first thickness; and a second portion with a second thickness different from the first thickness, wherein a non-zero loading between the first portion and the second portion is less than or equal to 6.6 nm. In an embodiment the first portion is located within a first region and the second portion is located within a second region, wherein there is a larger density of the plurality of nanostructures within the first region than the second region. In an embodiment one of the plurality of the nanostructures is located over a first fin, the first fin having a first width that is larger than a second width of the one of the plurality of the nanostructures. In an embodiment a difference between the first width and the second width is greater than 1.5 nm. In an embodiment the mask layer comprises silicon nitride. In an embodiment the semiconductor device further includes a liner adjacent to one of the plurality of the nanostructures, the liner having a first thickness adjacent to the isolation region and a second thickness adjacent to the metal gate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make

various changes, substitutions, and alterations herein without departing from the spirit and scope of the present disclosure.

What is claimed is:

1. A semiconductor device comprising:
a first mask over an isolation region over a semiconductor substrate, the first mask having a loading between a first region and a second region that is greater than zero and no larger than 6.6 nm;
a fin extending through the isolation region and the first mask; and
a gate structure over the first mask, the gate structure surrounding at least some of a plurality of nanostructures extending between a first source/drain region and a second source/drain region.

2. The semiconductor device of claim 1, wherein one of the plurality of the nanostructures is located over fin, the fin having a first width that is larger than a second width of the one of the plurality of the nanostructures.

3. The semiconductor device of claim 2, wherein a difference between the first width and the second width is greater than 1.5 nm.

4. The semiconductor device of claim 1, wherein the first region has a first density of nanostructures and the second region has a second density of nanostructures different from the first density of nanostructures.

5. The semiconductor device of claim 1, wherein the first mask has a first thickness in the first region of between about 5 nm and about 15 nm.

6. The semiconductor device of claim 5, wherein the first mask has a second thickness in the second region different than the first thickness, the second thickness being between about 5 nm and about 15 nm.

7. The semiconductor device of claim 1, wherein the first mask comprises silicon carbide.

8. A semiconductor device comprising:
an isolation region between fins over a semiconductor substrate;
a first dielectric material over the isolation region, the first dielectric material having a first thickness in a first region and a second thickness in a second region, the first thickness being different from the second thickness, wherein a loading between the first region and the second region is greater than zero and no larger than 6.6 nm; and
a metal gate over the semiconductor substrate, the metal gate surrounding at least some of a plurality of nanostructures, the plurality of nanostructures extending between a first source/drain region and a second source/drain region.

9. The semiconductor device of claim 8, wherein the first dielectric material comprises silicon nitride.

10. The semiconductor device of claim 8, wherein the first dielectric material comprises silicon carbide.

11. The semiconductor device of claim 8, wherein the first region has a first density of nanostructures and the second region has a second density of nanostructures different from the first density of nanostructures.

12. The semiconductor device of claim 8, wherein the first thickness is between about 5 nm and about 15 nm.

13. The semiconductor device of claim 12, wherein the second thickness is between about 5 nm and about 15 nm.

14. The semiconductor device of claim 8, wherein one of the plurality of nanostructures overlies one of the fins and has a width different from the one of the fins.

15. A method of manufacturing a semiconductor device, the method comprising:
forming an isolation region over a semiconductor substrate;
forming a mask layer over the isolation region; and
forming a metal gate over the semiconductor substrate, the metal gate surrounding at least some of a plurality of nanostructures extending between a first source/drain region and a second source/drain region, wherein after the forming the metal gate the isolation region is located between the metal gate and the semiconductor substrate, wherein after the forming the metal gate the mask layer is located between the metal gate and the isolation region, and wherein the mask layer comprises:
a first portion with a first thickness; and
a second portion with a second thickness different from the first thickness, wherein a non-zero loading between the first portion and the second portion is less than or equal to 6.6 nm.

16. The method of claim 15, wherein the first portion is located within a first region and the second portion is located within a second region, and wherein there is a larger density of the plurality of nanostructures within the first region than the second region.

17. The method of claim 15, wherein one of the plurality of the nanostructures is located over a first fin, the first fin having a first width that is larger than a second width of the one of the plurality of the nanostructures.

18. The method of claim 15, wherein the mask layer comprises silicon carbide.

19. The method of claim 15, wherein the mask layer comprises silicon nitride.

20. The method of claim 15, wherein the mask layer comprises silicon carbide nitride.
